(19) United States
(12) Patent Application Publication
(10) Pub. No.: US 2012/0273034 A1
(43) Pub. Date: Nov. 1, 2012

(54) METAL SUBSTRATE WITH INSULATION LAYER AND MANUFACTURING METHOD THEREOF, SEMICONDUCTOR DEVICE AND MANUFACTURING METHOD THEREOF, SOLAR CELL AND MANUFACTURING METHOD THEREOF, ELECTRONIC CIRCUIT AND MANUFACTURING METHOD THEREOF, AND LIGHT-EMITTING ELEMENT AND MANUFACTURING METHOD THEREOF

(75) Inventors: Keigo Sato, Ashigara-kami-gun (JP); Ryuichi Nakayama, Ashigara-kami-gun (JP); Shigenori Yuya, Ashigara-kami-gun (JP); Atsushi Mukai, Ashigara-kami-gun (JP); Shinya Suzuki, Ashigara-kami-gun (JP); Youta Miyashita, Ashigara-kami-gun (JP)

(73) Assignee: FUJIFILM CORPORATION, Minato-Ku, Tokyo (JP)

(21) Appl. No.: 13/520,115

(22) PCT Filed: Feb. 2, 2011
(86) PCT No.: PCT/JP2011/000577

§ 371 Date: Jun. 29, 2012

(30) Foreign Application Priority Data
Feb. 8, 2010 (JP) 2010-025367
Feb. 8, 2010 (JP) 2010-025646
Sep. 28, 2010 (JP) 2010-217073

(51) Int. Cl. H01L 21/31; H01L 33/44; C25D 5/00; H01L 31/02; B32B 15/01; H05K 3/00; H05K 7/04; F21V 21/00

(52) U.S. Cl. 136/252; 361/783; 438/778; 438/62; 361/760; 362/382; 428/613; 29/846; 205/112; 257/E21.24; 257/E33.06

(57) ABSTRACT

A metal substrate with an insulation layer includes a metal substrate having at least an aluminum base and an insulation layer formed on said aluminum base of said metal substrate. The insulation layer is a porous type anodized film of aluminum. The anodized film includes a barrier layer portion and a porous layer portion, and at least the porous layer portion has compressive strain at room temperature. a magnitude of the strain ranges from 0.005% to 0.25%. The anodized film has a thickness of 3 micrometers to 20 micrometers.

### TECHNICAL FIELD

The present invention relates to a metal substrate with an insulation layer having an anodized film as an insulation layer, which is used in a semiconductor device, solar cell or the like, and a manufacturing method thereof; a semiconductor device and manufacturing method thereof; a solar cell and manufacturing method thereof; an electronic circuit and manufacturing method thereof; and a light-emitting element and manufacturing method thereof. In particular, it relates to a metal substrate with an insulation layer wherein the anodized film has compressive strain (strain in the direction of compression) at room temperature and a manufacturing method thereof; a semiconductor device and manufacturing method thereof; a solar cell and manufacturing method thereof; an electronic circuit and manufacturing method thereof; and a light-emitting element and manufacturing method thereof.

### BACKGROUND ART

As the performance and functionality of electronic devices increase and their size and weight decrease, decreased size, reduced thickness and greater flexibility are required of the substrates on which light-emitting elements such as lasers, LEDs and organic ELs, and CPUs, electronic devices and electronic circuits are mounted. As flexible substrates, heat-resistant polymer films such as polyimide resins, polyethers and the like have been used.

Further, in semiconductor devices, because a large amount of heat is generated, countermeasures against heat are indispensible from the viewpoint of safety to prevent the problems of smoke, fire, etc., and from the viewpoint of reliability to prevent the problems of performance reduction and degradation due to heat. Heat generated by a device is radiated by heat conduction via the substrate, heat transfer to air and convection of air or by radiation, etc., but in general, the majority of heat radiation comes about due to heat conduction to the substrate. For this reason, substrates having high heat transfer characteristics are required, and novel heat-radiating materials and materials having high thermal conductivity have been developed (for example, refer to Patent Literature 1).

In general, organic materials have very low thermal conductivity (coefficient of thermal conductivity lambda is about 0.2 W/mK), and although there have been attempts to increase thermal conductivity by forming composites with thermally-conductive fillers, the improved conductivity has not exceeded 10 W/mK, which is insufficient.

Thus, substrates having an insulation layer on top of a body consisting of aluminum having high thermal radiation characteristics have come to be used (for example, refer to Patent Literature 2). Techniques that use organic materials such as epoxy resin have been proposed for insulation layers, but in this case there is the problem that the adhesion strength between the aluminum and organic material is weak, and there is risk of causing delamination during use of the electronic device over a long period. There have been attempts to improve on these problems, but they have not been sufficient.

Thus, at present, there have been attempts to use an anodized film as an insulation layer formed on a metal base (for example, refer to Patent Literature 3 and 4).

Patent Literature 3 discloses a heat-resistant insulated substrate comprising a metal substrate and an insulation layer arranged on at least one surface of the metal substrate via an intermediate layer made of an anodizable metal, wherein the insulation layer is made of the anodized substance of the metal that constitutes the intermediate layer.

In the heat-resistant insulated metal substrate of Patent Literature 3, either a stainless steel substrate, copper substrate, aluminum substrate, titanium substrate, iron substrate or iron alloy substrate may be used as the metal substrate. Note that in Patent Literature 3, when the intermediate layer is aluminum, the anodized film is an Al₂O₃ (alumina) film.

Further, the heat-resistant insulated substrate of Patent Literature 3 is employed in sensors or microreactors, and its usage temperature is assumed to be at least 200 degree C. Additionally, Patent Literature 1 states that a laminate of an intermediate layer and an insulation layer can be formed in a desired pattern by photolithography.

In an Al₂O₃ film obtained by anodizing aluminum, the heat resistance of the anodized film itself is extremely high. Further, Al₂O₃ is also insulating because it is a ceramic. Additionally, formation of the anodized film is carried out industrially by a roll to roll process, and productivity is high.

Further, Patent Literature 4 describes a solar cell having a photoelectric conversion layer on a solar cell substrate obtained by forming a first insulating oxide film having a plurality of pores by anodization on an aluminum substrate, and then forming a second insulating film on some of the pores to obtain a sealing ratio of 5-80%.

When using an anodized film for a heat-resistant insulated substrate, the topics of concern are the ability to withstand solder reflow during device mounting, heat resistance during the manufacture of semiconductor elements, bending resistance for a flexible substrate during roll-to-roll manufacturing, and long-term durability and strength. These are all problems that arise due to the anodized film not withstanding stress and cracks occurring when stress is applied to the anodized film from the outside.

Cracking in the anodized film formed on Al material is caused by the fact that the linear expansion coefficient of Al (23 ppm/K) is larger than that of the anodized film. Here, the linear expansion coefficient of the anodized film is understood by the inventors to be 5 ppm/K. Since the linear thermal expansion coefficient of aluminum is 23 ppm/K, cracking is believed to arise due to the fact that the anodized film cannot withstand the tensile stress in the anodized film caused by the large difference in linear thermal expansion coefficient of 18 ppm/K due to a rise in temperature.

For example, when semiconductor elements or the like are mounted on the substrate, the process of solder reflow is often used, which is a technique having a low cost and a short process time. With this technique, a large amount of thermal stress is incurred by the substrate because the entire mounted substrate is heated by infrared rays or hot air. In the case of silver/tin eutectic solder, for example, the solder reflow conditions are 30 seconds at 210 degree C., and it is required that cracking and so forth do not occur in the insulation layer and that the insulation properties of the substrate are not diminished throughout the process.

However, when a conventional anodized substrate is used, heat resistance is poor, and cracking occurs in the anodized film and insulation properties are reduced in the solder reflow process.

As is clear from Non-Patent Literature 1, it is known that cracking occurs when an anodized film on an Al substrate is heated to 120 degree C. or above, and once cracking occurs, there are the problems that insulation properties deteriorate, and in particular, leakage current increases.

Further, there is also the problem of deterioration over time, because in the usage environment of the actual device, high temperature results from heat generated from the devices while operating, and the substrate repeatedly undergoes thermal expansion and contraction due to repeated cycling between room temperature and high temperature.

When temperature increases and decreases are repeated over a long period, stress is concentrated inside the anodized film, on the surface of the anodized film or at the interface between the anodized film and the metal base, and there is a problem in cracking resistance in that generation and propagation of cracks readily occur. In particular, when a substrate in which an anodized film is formed as an insulation layer is used as a substrate requiring insulation properties for electronic devices, when cracks are generated in the insulation layer, they become pathways for leakage current and cause a reduction in insulation properties. Further, in the worst case there is risk of insulation breakdown due to leakage current that uses the cracks as pathways.

Additionally, the problem of reduced insulation properties due to cracking may also occur in cases where impact is incurred or bending strain is incurred during transport in a roll to roll process.

Thus, use of a substrate with an anodized film as an insulated substrate has the various problems of heat resistance, bending resistance and long-term reliability. Thus, attempts have been made since the past to improve on the various problems of anodized films (for example, refer to Patent Literature 5-10).

Patent Literature 5 discloses an anodized aluminum alloy comprising an aluminum alloy which contains 0.1-2.0 mass % Mg, 0.1-2.0 mass % Si and 0.1-2.0 mass % Mn as alloy components, wherein the contained amounts of Fe, Cr and Cu are each restricted to 0.03 mass % or less and the remainder is made from Al and unavoidable impurities, and an anodized film formed on the surface of the aluminum alloy. In this alloy, there are locations where hardness differs in the direction of thickness of the anodized film, and the difference between the location of maximum hardness and the location of minimum hardness is at least 5 as measured by Vickers hardness. In the anodized aluminum alloy of Patent Literature 5, even if cracking occurs, propagation of cracks is inhibited, such that cracks do not extend as far as the aluminum alloy itself.

Patent Literature 6 discloses that, in a thin fuser roller used in a photocopier which uses a digital photography process, a difference in hardness is provided, such that the hardness of the side farther from the internal surface of the roller material is greater than the hardness of the side nearer to the inner surface of the roller material. The thin fuser roller of Patent Literature 6 has the objectives of high strength against delamination following deformation and improved cracking resistance.

Further, in the resin-coated aluminum alloy member of Patent Literature 7, an anodized film which has undergone sealing of anodic oxide coating is formed on the surface portion of an aluminum alloy base, and a resin coating layer of fluorine resin or silicon resin is formed on top of the anodized film, and net-like cracks are formed in the anodized film. Resin which continues from the resin coating layer on top infiltrates and impregnates the net-like cracks in the anodized film.

In Patent Literature 7, the resin coating layer which is unified with the resin inside the cracks is held strongly against the anodized film and exhibits very high adhesion to it, because the resin inside the cracks has the form of a net which continues and branches in the surface direction along the net-like cracks.

Patent Literature 8 discloses an anodized film having excellent cracking resistance and corrosion resistance as a material for parts used in vacuum chambers. Force is applied to the anodized film due to the difference in linear thermal expansion coefficients of the aluminum alloy base and the anodized film, and when the force exceeds that withstood by the film, cracking occurs. The force applied to the film becomes smaller as the void ratio of the porous anodized film gets larger, while on the other hand, the force withstood by the film becomes larger as the true density gets larger. Therefore, the larger the void ratio and true density of the anodized film, the higher the cracking resistance of the anodized film.

Patent Literature 9 describes that breakage during heating, which causes conduction, is inhibited by causing the structure of the anodized film to have pores which extend in the direction of growth in the anodized layer and voids which intersect them in the substantially perpendicular direction. As a result, even when used as a large-area base material, sufficient insulation properties can be assured along the entire surface.

As described above, the magnitude of internal stress and the generation of cracks are closely related. In the past, internal stress of an anodized film has been described in Patent Literature 10, etc. In Patent Literature 10, it is shown that in an anodized film of 3 micrometers or more, internal stress is tensile stress. Further, Patent Literature 10 discloses that it is best to minimize stress in the tensile direction in order to increase the strength of the aluminum anodized film. In an anodized film that has compressive stress at room temperature, even if stress is concentrated inside the anodized film, on the surface of the anodized film or at the interface between the anodized film and the aluminum due to changes over time, it is believed that this is not linked with crack generation, and cracking resistance is excellent due to the fact that compressive strain acts on the film.

However, an anodized film has compression stress when its film thickness is less than 3 micrometers, and it turns into tensile stress when thickness is 3 micrometers or more. The reason for this is described as follows.

In general, an anodized film obtained in an acidic electrolytic solution is made up of a dense layer called a barrier layer present near the interface with aluminum, and a layer of porous substance called a porous layer present on the surface side. Of these layers, the barrier layer has compression stress. This is because when anodized aluminum is formed from simple aluminum, it is accompanied by volume expansion. On the other hand, it is known that the porous layer has tensile stress. For this reason, it is known that when the anodized film is thick, the effects of the porous layer are greatly seen in the entire anodized film, such that tensile stress is exhibited in the entire anodized film. In Patent Literature 10, it is described that there is compression stress when the film thickness is less than 3 micrometers, and it turns into tensile stress when thickness is 3 micrometers or more.

### CITATION LIST

### Patent Literature

[Patent Literature 1] JP 2010-47743 A
[Patent Literature 2] JP 2630858 B
[Patent Literature 3] JP 2009-132996 A
[Patent Literature 4] JP 2009-267664 A
[Patent Literature 5] JP 2009-46747 A
[Patent Literature 6] JP 2002-196603 A
[Patent Literature 7] JP 3210611 B
[Patent Literature 8] JP 2010-133003 A
[Patent Literature 9] JP 2000-349320 A
[Patent Literature 10] JP S61-19796 A

### NON-PATENT LITERATURE

[Non-Patent Literature 1] Masashi KAYASHIMA, Masakatsu MUSHIRO, Tokyo Metropolitan Industrial Technology Research Institute, Research Report No. 3, December 2000, p. 21

### SUMMARY OF INVENTION

### Technical Problem

In Patent Literature 5-7, inhibition of crack development and control of the means of crack initiation are required, but there is the problem that these do not substantially prevent crack generation.

As described above, the anodized film cannot withstand tensile stress that arises due to a difference in thermal expansion between the anodized film and the base, and if it exceeds the fracture limit, cracks will be generated. That is, the temperature at which tensile stress of the fracture limit is incurred is called the crack generation temperature of the anodized film.

Here, the fracture limit of the anodized aluminum film can be estimated as follows. The inventors have found that the internal strain at room temperature of an ordinary anodized aluminum film is tensile strain of about 0.005-0.06%, and the linear thermal expansion coefficient is about 5 ppm/K. In the case of an anodized film on an aluminum substrate, the linear thermal expansion coefficient of aluminum is 23 ppm/K, and thus tensile strain is applied to the anodized film in a proportion of 18 ppm/K due to a rise in temperature. This is schematically shown in FIG. 6. Since the crack generation temperature is roughly 120-150 degree C., it has been shown that cracks are generated when the anodized film incurs tensile strain of roughly 0.16-0.23%. This strain is consistent with the fact that the tensile fracture limit of ceramics is generally 0.1-0.2%.

Here, it is believed that when the anodized film which has compressive strain is heated, the internal strain at room temperature of the anodized film may cause the temperature at which 0.16-0.23% tensile strain is incurred, which is the aforementioned fracture limit, to rise as shown in FIG. 6, increasing the crack generation temperature.

Patent Literature 10 also discloses an anodized film in which the internal stress is compressive stress, but it describes that when the thickness of the anodized film of Patent Literature 10 exceeds 3 micrometers, it turns into tensile stress. If the film thickness is 3 micrometers or less, the internal stress is compressive and it can be expected that cracks will not be readily generated, but as described below, it is difficult to use the substrate with an anodized film disclosed in Patent Literature 10 as a metal substrate with an insulation layer due to insulation properties.

It is known that the insulation properties of anodized aluminum depend on the thickness of the anodized film. When the anodized film of Patent Literature 10 is to be used for an insulated substrate, sufficient insulation properties cannot be assured if the film thickness on which compressive stress acts is less than about 3 micrometers. Looking at insulation breakdown voltage as an index of insulation properties, an insulation breakdown voltage of at least several hundred volts is required in, for example, semiconductors to which high voltage is applied, solar cells or semiconductor devices expected to operate at high temperature, etc. For example, in applications as substrates for solar cells, single cells are integrated on the substrate, and by serially connecting a plurality of cells, an output voltage of several tens to several hundreds of volts is obtained. To obtain an insulation breakdown voltage of about 200 V, an anodized film having a thickness exceeding about 3 micrometers is required. To obtain such an insulation film, there is no choice but to make the porous layer thicker, and naturally the anodized film as a whole comes to have tensile stress. For this reason, the topics of concern are heat resistance during the manufacture of semiconductor elements, bending resistance as a flexible substrate during roll-to-roll manufacturing, and long-term durability and strength.

An objective of the present invention is to provide a metal substrate with an insulation layer and manufacturing method thereof, whereby generation of cracks in an anodized film formed as an insulation layer is inhibited even if it is exposed to a high-temperature environment, incurs bending strain or undergoes temperature cycling over a long period, and a semiconductor device and manufacturing method thereof, a solar cell and manufacturing method thereof, an electronic circuit and manufacturing method thereof and a light-emitting element and manufacturing method thereof which use this metal substrate with an insulation layer, which solve the problems based on the above-described prior art.

### Solution to Problem

The present invention improves cracking resistance at high temperature by controlling internal stress of the anodized film and using compressive strain, and it assures sufficient insulation properties by having an anodized film thickness of at least several micrometers. In the past, an anodized film having both of these features did not exist, and further, as described below, the principle thereof is completely different from that of prior art.

To achieve the aforementioned objective, according to a first aspect of the present invention, there is provided a metal substrate with an insulation layer comprising a metal substrate having at least an aluminum base, and a porous aluminum anodized film formed on the aluminum base of the metal substrate, wherein the anodized film is made up of a barrier layer portion and a porous layer portion, and at least the porous layer portion has compressive strain at room temperature.

In prior art, the relationship between the strain of the anodized film and cracking resistance was focused on. Further, with regard to the magnitude of strain, an anodized film in which the porous layer portion has strain in the direction of tension is known in Patent Literature 7, etc., but the present invention differs from prior known art in that the porous layer portion has compressive strain at room temperature.

In this case, the magnitude of the strain is preferably 0.005-0.25%.

If compressive strain is less than 0.005%, although there is compressive strain, almost no substantial compressive force acts on the anodized film, and the effect of cracking resistance is not readily obtained. For this reason, when it is exposed to a high-temperature environment during film formation, incurs bending strain during roll-to-roll manufacturing or in the end product, undergoes temperature cycling over a long period or incurs external impact or stress, cracking occurs in the anodized film formed as an insulation layer, causing insulation properties to diminish.

On the other hand, at the upper limit of compressive strain, the insulation properties definitely diminish because cracks are generated, the anodized film bulges up, its flatness decreases and delamination occurs due to the anodized film delaminating and strong compressive strain acting on the anodized film. For this reason, compressive strain of 0.25% or less is preferred. It is more preferably 0.20% or less, and particularly preferably 0.15% or less.

In this case, the anodized film preferably has a thickness of 3 micrometers to 20 micrometers.

Insulation properties due to having a film thickness of at least 3 micrometers, heat resistance characteristics during deposition due to having compressive stress at room temperature, as well as long-term reliability can be achieved.

The film thickness is preferably at least 3 micrometers and at most 20 micrometers, and more preferably at least 5 micrometers and at most 20 micrometers, and particularly preferably at least 5 micrometers and at most 15 micrometers.

If the film is extremely thin, there is risk that it will be incapable of electrical insulation and preventing damage from mechanical impact during handling. Furthermore, insulation properties and heat resistance drop rapidly, and there is great deterioration over time. This is because, due to the film being thinner, the effect of asperities on the anodized film surface becomes relatively large and cracks tend to form with these as the base points, and additionally, insulation properties diminish because the effects of metal precipitates, intermetallic compounds and voids in the anodized film arising from metal impurities contained in the aluminum become relatively large, and cracks tend to form by fracture when the anodized film incurs external impact or stress. As a result, if the anodized film is less than 3 micrometers, insulation properties diminish, and therefore it cannot be used in applications as a flexible heat-resistant substrate or in production by a roll to roll process.

Further, if the film thickness is excessively large, it is not desirable because flexibility is reduced and the cost and time required for anodization increase. Further, bending resistance and thermal strain resistance are reduced. The cause of reduced bending resistance is hypothesized to be that the stress distribution in the cross-sectional direction becomes greater and a localized stress concentration tends to arise because the magnitude of tensile stress at the interface between the surface of the anodized film and the aluminum differs when the anodized film is bent. The cause of reduced strain resistance is hypothesized to be that the stress distribution in the cross-sectional direction becomes greater and a localized stress concentration tends to arise because large stress acts on the interface with the aluminum when tensile stress acts on the anodized film due to thermal expansion of the base. As a result, if the anodized film is greater than 20 micrometers, bending resistance and thermal strain resistance diminish, and therefore it cannot be used in applications as a flexible heat-resistant substrate or in production by a roll to roll process. Further, insulation reliability is also diminished.

The above-described anodized film is a porous anodized aluminum film. This film is made up of two layers: a barrier layer and a porous layer. As described above, in general, the barrier layer has compressive stress and the porous layer has tensile stress, but the anodized film of the present invention is a porous anodized film made up of a barrier layer and a porous layer wherein the porous layer has compressive stress. For this reason, even if the coating thickness is 3 micrometers or more, the anodized film as a whole can be put under compressive stress, and an insulating film in which there is no crack generation due to differences in thermal expansion during film formation and which has excellent long-term reliability near room temperature is provided.

Further, the above-described anodized film may have either a regularized porous structure or an irregular porous structure.

Further, the metal substrate is made from the aluminum base, and the anodized film is preferably formed on at least one surface of the aluminum base.

Further, in the metal substrate, it is preferred that the aluminum base is provided on at least one surface of the metal base.

Further, in the metal substrate, it is preferred that the aluminum base is arranged on at least one surface of a metal base made from a metal different from aluminum, and the anodized film is formed on the surface of the aluminum base.

Further, in the metal substrate, it is preferred that the aluminum base is arranged on at least one surface of a metal base made from a metal having a larger Young's modulus than aluminum, and the anodized film is formed on the surface of the aluminum base.

Further, it is preferred that the thermal expansion coefficient of the metal base is greater than that of the anodized film, and smaller than that of aluminum.

Further, it is preferred that the Young's modulus of the metal base is greater than that of the anodized film, and greater than that of aluminum.

Further, in the metal substrate, it is preferred that the metal base and the aluminum base are unified by pressure welding (compression bonding).

Further, it is preferred that the compressive strain of the anodized film is formed by anodizing the aluminum base of the metal substrate in the state where the metal substrate is elongated more than in the state of use at room temperature, or formed by anodizing the aluminum base in a 50-98 degree C. acidic aqueous solution, or formed by forming the anodized film by anodizing the aluminum base and then heat-treating the anodized film.

Further, the anodized film that has compressive strain is preferably formed by anodization using a roll to roll process.

Further, the anodized film that has compressive strain is preferably an anodized film obtained by heating to 100-600 degree C., and in this case, more preferably 100-200 degree C.

Further, the anodized film that has compressive strain is preferably an anodized film obtained by heating an anodized film that has tensile strain.

Further, the heating time for forming the anodized film that has compressive strain is preferably from 1 second to 100 hours.

Further, the anodized film that has compressive strain is preferably obtained by a manufacturing method wherein it is heat-treated using a roll to roll process.

Also, the metal substrate with an insulation layer of the present invention comprises a metal substrate having at least an aluminum base and an insulation layer formed on the aluminum base of the metal substrate, wherein the insulation layer is an aluminum anodized film, and compressive stress acts on the anodized film at room temperature, and the magnitude of the compressive stress is 2.5-300 MPa.

According to a second aspect of the present invention, there is provided a manufacturing method of a metal substrate with an insulation layer comprising a step of forming a porous anodized aluminum film, which serves as an insulation layer, made up of a barrier layer portion and a porous layer portion, wherein at least the porous layer portion has compressive strain at room temperature, on the aluminum base of a metal substrate having at least an aluminum base.

In this case, the step of forming the porous anodized aluminum film having compressive strain is preferably formation of a porous anodized aluminum film in the state where the metal substrate is elongated more than in the state of use at room temperature.

Further, the step of forming the anodized film is preferably performed by electrolysis in a solution having a temperature of 50-98 degree C., and is preferably performed in an aqueous solution, even more preferably in a 50-98 degree C. acidic aqueous solution having a pKa at 25 degree C. of 2.5-3.5.

Further, the step of forming the anodized film and the step of providing compressive strain are preferably performed in an integrated manner by a roll to roll process.

Further, the step of providing compressive strain is preferably the application of strain with a magnitude of 0.005-0.25% at room temperature to the anodized film in the direction of compression, brought about by cooling the anodized film formed at 50-98 degree C. to room temperature.

In the metal substrate, it is preferred that the aluminum base is unified by pressure welding on at least one surface of a metal base made from a metal different from aluminum, and the anodized film is formed on the surface of the aluminum base.

Further, the present invention provides a manufacturing method of a metal substrate with an insulation layer, wherein the step of forming the porous anodized aluminum film having compressive strain comprises a step of anodization treatment, which forms the porous anodized aluminum film on the aluminum base of the metal substrate, and a step of heat treatment, which heat-treats the formed anodized film at a heating temperature of 100-600 degree C.

In this case, the heat treatment conditions of the heat treatment step preferably include a heating temperature of 100-200 degree C. and a holding time of 1 second to 100 hours.

In particular, if a substrate made only of aluminum is used, the heat treatment step is preferably performed at a heating temperature at or below the softening point of the aluminum base, more preferably at or below 200 degree C., and even more preferably at or below 150 degree C.

Further, the anodized film that is heat treated in the heat treatment step preferably has tensile strain.

Further, either one or both of the anodization treatment step and/or heat treatment step is preferably performed by a roll to roll process.

Further, the thickness of the anodized film is preferably 3-20 micrometers, and it is preferred that after the heat treatment step, the anodized film is provided with strain with a magnitude of 0.005-0.25% at room temperature in the direction of compression.

Further, in the metal substrate, it is preferred that the aluminum base is unified by pressure welding on at least one surface of the metal base made from a metal having a larger Young's modulus than aluminum, and the anodized film is formed on the surface of the aluminum base.

Note that in the second aspect of the present invention, any of the metal substrates of the metal substrate with an insulation layer of the first aspect of the present invention may be used.

According to a third aspect of the present invention, there is provided a semiconductor device that employs the metal substrate with an insulation layer of the first aspect of the present invention.

In this case, in a semiconductor device in which semiconductor elements are formed on a metal substrate with an insulation layer that is the metal substrate with an insulation layer of the first aspect of the present invention that has undergone heat treatment, the semiconductor elements may be continuously formed on the metal substrate with an insulation layer without reducing the temperature of the metal substrate with an insulation layer to room temperature after heat treatment. The formation temperature of the semiconductor elements is preferably higher than the heating temperature of the heat treatment step. In this case, the metal substrate with an insulation layer and the semiconductor elements may be formed in an integrated manner by a roll to roll process.

Further, in a semiconductor device in which semiconductor elements are formed on a metal substrate with an insulation layer, the metal substrate with an insulation layer and the semiconductor elements may be formed in an integrated manner by a roll to roll process.

According to a fourth aspect of the present invention, there is provided a manufacturing method of a semiconductor device comprising a step of manufacturing a metal substrate with an insulation layer by the manufacturing method of a metal substrate with an insulation layer of the second aspect of the present invention, and a step of forming semiconductor elements on the metal substrate with an insulation layer, wherein the step of manufacturing a metal substrate with an insulation layer and the step of forming semiconductor elements are performed in an integrated manner by a roll to roll process.

When manufacturing a metal substrate with an insulation layer by the manufacturing method of a metal substrate with an insulation layer of the second aspect of the present invention, the semiconductor elements may be continuously formed on the metal substrate with an insulation layer without reducing the temperature of the metal substrate with an insulation layer to room temperature after heat treatment. The formation temperature of the semiconductor elements is preferably higher than the heating temperature of the heat treatment step. In this case, the step of manufacturing the metal substrate with an insulation layer and the step of forming the semiconductor elements may be performed in an integrated manner by a roll to roll process.

According to a fifth aspect of the present invention, there is provided a solar cell that employs the metal substrate with an insulation layer of the first aspect of the present invention.

In this case, it is preferred that a compound-based photoelectric conversion layer is formed on the metal substrate with an insulation layer.

Further, the photoelectric conversion layer is preferably formed of a compound semiconductor having at least one kind of chalcopyrite structure.

Further, the photoelectric conversion layer is preferably formed of at least one kind of compound semiconductor composed of a group Ib element, a group Mb element, and a group VIb element.

Further, in the photoelectric conversion layer, the group Ib element is preferably at least one kind selected from the group consisting of Cu and Ag; the group IIIb element is preferably at least one kind selected from the group consisting of Al, Ga, and In; the group VIb element is preferably at least one kind selected from the group consisting of S, Se, and Te.

In a solar cell in which at least a compound-based photoelectric conversion layer is formed on a metal substrate with an insulation layer which is the metal substrate with an insulation layer of the first aspect of the present invention that has undergone heat treatment, the compound-based photoelectric conversion layer may be continuously formed on the metal substrate with an insulation layer without reducing the temperature of the metal substrate with an insulation layer to room temperature after heat treatment. The formation temperature of the compound-based photoelectric conversion layer is preferably higher than the heating temperature of the heat treatment step. In this case, the metal substrate with an insulation layer and the compound-based photoelectric conversion layer may be formed in an integrated manner by a roll to roll process.

Further, in a solar cell in which at least a compound-based photoelectric conversion layer is formed on a metal substrate with an insulation layer, the metal substrate with an insulation layer and the compound-based photoelectric conversion layer may be formed in an integrated manner by a roll to roll process.

According to a sixth aspect of the present invention, there is provided a manufacturing method of a solar cell comprising a step of manufacturing a metal substrate with an insulation layer by the manufacturing method of a metal substrate with an insulation layer of the second aspect of the present invention, and a film deposition step of forming at least a compound-based photoelectric conversion layer on the metal substrate with an insulation layer, wherein the step of manufacturing a metal substrate with an insulation layer and the film deposition step are performed in an integrated manner by a roll to roll process.

When manufacturing a metal substrate with an insulation layer by the manufacturing method of a metal substrate with an insulation layer of the second aspect, the compound-based photoelectric conversion layer may be continuously formed on the metal substrate with an insulation layer without reducing the temperature of the manufactured metal substrate with an insulation layer to room temperature after heat treatment. The formation temperature of the compound-based photoelectric conversion layer is preferably higher than the heating temperature of the heat treatment step. In this case, the step of manufacturing the metal substrate with an insulation layer and the film deposition step may be performed in an integrated manner by a roll to roll process.

According to a seventh aspect of the present invention, there is provided an electronic circuit that employs the metal substrate with an insulation layer of the first aspect of the present invention.

In this case, in an electronic circuit in which electronic elements are formed on a metal substrate with an insulation layer which is the metal substrate with an insulation layer of the first aspect of the present invention that has undergone heat treatment, the electronic elements may be continuously formed on the metal substrate with an insulation layer without reducing the temperature of the metal substrate with an insulation layer to room temperature after heat treatment. The formation temperature of the electronic circuit is preferably higher than the heating temperature of the heat treatment step. In this case, the metal substrate with an insulation layer and the electronic circuit may be formed in an integrated manner by a roll to roll process.

Further, in an electronic circuit in which electronic elements are formed on a metal substrate with an insulation layer, the metal substrate with an insulation layer and the electronic elements may be formed in an integrated manner by a roll to roll process.

According to an eighth aspect of the present invention, there is provided a manufacturing method of an electronic circuit comprising a step of manufacturing a metal substrate with an insulation layer by the manufacturing method of a metal substrate with an insulation layer of the second aspect of the present invention, and a step of forming electronic elements on the metal substrate with an insulation layer.

In this case, the step of manufacturing the metal substrate with an insulation layer and the step of forming the electronic elements may be performed in an integrated manner by a roll to roll process.

When manufacturing a metal substrate with an insulation layer by the manufacturing method of a metal substrate with an insulation layer of the second aspect of the present invention, the electronic elements may be continuously formed on the metal substrate with an insulation layer without reducing the temperature of the manufactured metal substrate with an insulation layer to room temperature after heat treatment. The formation temperature of the electronic elements is preferably higher than the heating temperature of the heat treatment step. In this case, the step of manufacturing the metal substrate with an insulation layer and the step of forming the electronic elements may be performed in an integrated manner by a roll to roll process.

According to a ninth aspect of the present invention, there is provided a light-emitting element that employs the metal substrate with an insulation layer of the first aspect of the present invention.

In this case, in a light-emitting element in which light-emitting devices are formed on a metal substrate with an insulation layer which is the metal substrate with an insulation layer of the first aspect of the present invention that has undergone heat treatment, the light-emitting devices may be continuously formed on the metal substrate with an insulation layer without reducing the temperature of the metal substrate with an insulation layer to room temperature after heat treatment. The formation temperature of the light-emitting devices is preferably higher than the heating temperature of the heat treatment step. In this case, the metal substrate with an insulation layer and the light-emitting devices may be formed in an integrated manner by a roll to roll process.

Further, according to the first aspect of the present invention, a light-emitting device in which light-emitting elements are formed on a metal substrate with an insulation layer, the metal substrate with an insulation layer and the light-emitting elements may be formed in an integrated manner by a roll to roll process.

According to a tenth aspect of the present invention, there is provided a manufacturing method of a light-emitting device comprising a step of manufacturing a metal substrate with an insulation layer by the manufacturing method of a metal substrate with an insulation layer of the second aspect of the present invention, and a step of forming light-emitting elements on the metal substrate with an insulation layer.

In this case, the step of manufacturing the metal substrate with an insulation layer and the step of forming the light-emitting elements may be performed in an integrated manner by a roll to roll process.

When manufacturing a metal substrate with an insulation layer by the manufacturing method of a metal substrate with an insulation layer of the second aspect of the present invention, the light-emitting elements may be continuously formed on the metal substrate with an insulation layer without reducing the temperature of the manufactured metal substrate with an insulation layer to room temperature after heat treatment. The formation temperature of the light-emitting elements is preferably higher than the heating temperature of the heat treatment step. In this case, the step of manufacturing the metal substrate with an insulation layer and the step of forming the light-emitting elements may be performed in an integrated manner by a roll to roll process.

### ADVANTAGEOUS EFFECTS OF INVENTION

According to the present invention, a porous anodized aluminum film is provided as an insulation film formed on the surface of a metal substrate comprising at least an aluminum base, and in the anodized film, at least the porous layer portion has compressive strain at room temperature, and the magnitude of the strain is 0.005-0.25%. As a result, even if stress is concentrated inside the anodized film, at the surface of the anodized film or at the interface between the anodized film and the metal base due to changes over time, it does not readily lead to generation of cracks because compressive strain acts on the anodized film, and a metal substrate with an insulation layer that has excellent cracking resistance can be obtained.

The metal substrate with an insulation layer of the present invention uses a porous anodized aluminum film as the insulation layer. Since this anodized aluminum film is ceramic, chemical changes do not readily occur at high temperatures, enabling use of the anodized aluminum film as an insulation layer that offers high reliability without cracking. As a result, the metal substrate with an insulation layer of the present invention makes it possible to obtain a metal substrate with an insulation layer that is highly resistant to thermal strain and does not undergo performance degradation even when exposed to temperature conditions of 500 degree C. or above. Further, since it has a film thickness of at least 3 micrometers, a metal substrate with an insulation film having good insulation properties can be obtained.

Further, according to the present invention, because a metal substrate having an aluminum base may be used, it is flexible, and as a result, a semiconductor device, solar cell and the like can be manufactured by the roll-to-roll process, and therefore productivity can be improved. Further, the obtained device such as a solar cell may be mounted on a curved surface such as a roof or wall.

Further, according to the present invention, the semiconductor devices, solar cells, electronic circuits and light-emitting elements have excellent durability and storage life because the used metal substrate with an insulation layer has excellent cracking resistance and excellent insulation properties.

### BRIEF DESCRIPTION OF DRAWINGS

FIG. 1A is a cross section view schematically illustrating a metal substrate with an insulation layer according to an embodiment of the present invention.

FIG. 1B is a cross section view schematically illustrating another example of a metal substrate with an insulation layer according to an embodiment of the present invention.

FIG. 1C is a cross section view schematically illustrating yet another example of a metal substrate with an insulation layer according to an embodiment of the present invention.

FIG. 2 is a graph which schematically illustrates the strain applied to the anodized film in the cases where the compressive strain is 0.09% and 0.16%, and a conventional anodized film.

FIG. 3 is a graph which schematically illustrates the strain applied to the anodized film in the cases where the linear thermal expansion coefficient of the composite substrate is 17 ppm/K and 10 ppm/K, and a conventional anodized film.

FIG. 4 is a graph which schematically illustrates the heat treatment conditions, with annealing temperature on the vertical axis and annealing time on the horizontal axis.

FIG. 5 is a cross section view schematically illustrating a thin-film solar cell using the metal substrate with an insulation layer according to an embodiment of the present invention.

FIG. 6 is a graph which schematically illustrates the strain applied to a conventional anodized film.

### DESCRIPTION OF EMBODIMENTS

On the following pages, the metal substrate with an insulation layer and manufacturing method thereof, solar cell and manufacturing method thereof, electronic circuit and manufacturing method thereof and light-emitting element and manufacturing method thereof according to the present invention will be described in detail with reference to the preferred embodiments shown in the accompanying drawings.

The substrate with an insulation layer of the present invention will be described below.

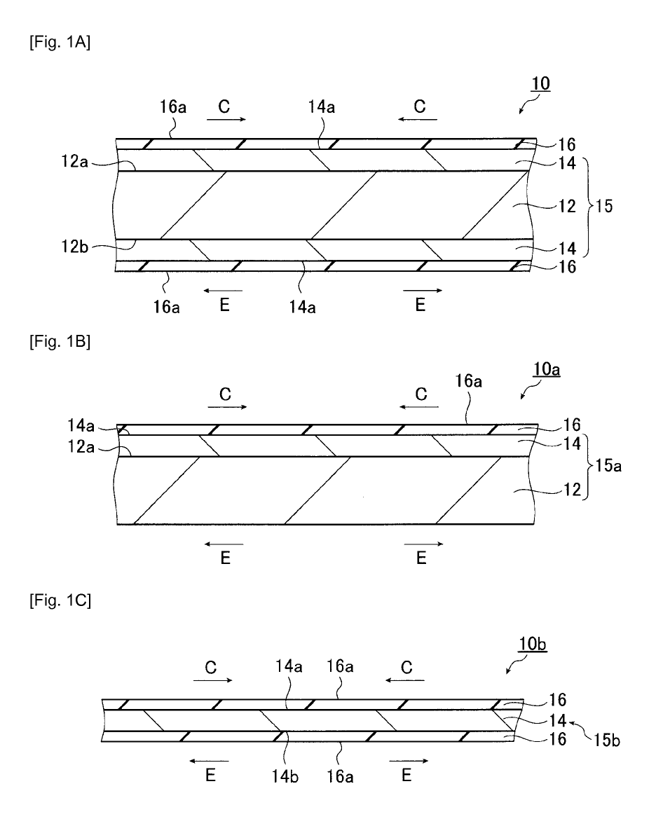

As shown in FIG. 1A, the substrate 10 is a metal substrate with an insulation layer comprising a metal base 12, an aluminum base 14 (hereinafter “Al base 14”) having aluminum as its main component, and an insulation layer 16 which electrically insulates the metal base 12 and Al base 14 from the outside. The insulation layer 16 is constructed from an anodized film.

In the substrate 10, the aluminum base 14 is formed on the front surface 12a of the metal base 12, and the insulation layer 16 is formed on the front surface 14a of the Al base 14. Further, the aluminum base 14 is formed on the back surface 12b of the metal base 12, and the insulation layer 16 is formed on the front surface 14a of the Al base 14. In the substrate 10, the Al bases 14 and insulation layers 16 are formed symmetrically centered around the metal base 12.

Note that the metal base 12 and two Al bases 14 are laminated and unified to form a metallic substrate 15.

The substrate 10 of this embodiment is used as a substrate of a semiconductor device, photoelectric conversion element and thin-film solar cell, and is flat in shape, for example. The shape and size of the substrate 10 are suitably determined in accordance with the size, etc., of the semiconductor device, light-emitting element, photoelectric conversion element and thin-film solar cell in which it is used. When used in a thin-film solar cell, the substrate 10 is square in shape, with the length of one side exceeding 1 m, for example.

In the substrate 10, a metal different from aluminum is used in the metal base 12. As the different metal, for example, a metal or alloy having a higher Young's modulus than aluminum and aluminum alloy are used. Further, it is preferred that the thermal expansion coefficient of the metal base 12 is greater than that of the anodized film that constitutes the insulation layer 16, and smaller than that of aluminum. Further, it is preferred that the Young's modulus of the metal base 12 is greater than that of the anodized film that constitutes the insulation layer 16, and greater than that of aluminum.

Considering the facts described above, in this embodiment, a steel material such as carbon steel or ferrite stainless steel is used in the metal base 12. Furthermore, since the steel material used in the metal base 12 exhibits greater heat-resistant strength at temperatures of 300 degree C. and higher than does aluminum alloy, a substrate 10 with good heat resistance is obtained.

The carbon steel used for the metal base 12 is a carbon steel for mechanical structures having a carbon content of 0.6 mass % or less, for example. Examples of materials used as the carbon steel for mechanical structures include materials generally referred to as SC materials.

Further, the materials that can be used as the ferrite stainless steel include SUS430, SUS405, SUS410, SUS436, and SUS444.

Examples of materials that can be used as the steel material in addition to the above include materials generally referred to as SPCC materials (cold-rolled steel sheets).

Note that other than the above, the metal base 12 may be made of a kovar alloy (5 ppm/K), titanium, or a titanium alloy. The material used as the titanium is pure titanium (9.2 ppm/K), and the materials used as the titanium alloy are the wrought alloys Ti-6Al-4V and Ti-15V-3Cr-3Al-35n. These metals also are used in a flat shape or foil shape.

The thickness of the metal base 12 affects flexibility, and is thus preferably thin, within a range not associated with an excessive lack of rigidity.

In the substrate 10 of this embodiment, the thickness of the metal base 12 is, for example, 10-800 micrometers, and preferably 30-300 micrometers. More preferably, the thickness is 50-150 micrometers. The reduced thickness of the metal base 12 is also preferred from a raw material cost standpoint.

When the metal base 12 is to be flexible, the metal base 12 is preferably ferrite stainless steel.

The Al base 14 comprises aluminum as its main component, meaning that the aluminum content is at least 90 mass %.

Examples of materials used as the Al base 14 include aluminum and aluminum alloy.

The Al base 14 can be formed, for example, of publicly known materials indicated in Aluminum Handbook, 4th edition (published in 1990 by Japan Light Metal Association) including, more specifically, Class 1000 alloys such as JIS1050 material and JIS1100 material, Class 3000 alloys such as JIS3003 material, JIS3004 material, and JIS3005 material, Class 6000 alloys such as JIS6061 material, JIS6063 material, and JIS6101 material, and internationally registered alloy 3103A etc.

The aluminum or aluminum alloy used for the Al base 14 preferably does not contain any unnecessary intermetallic compounds. Specifically, aluminum with a purity of at least 99 mass % which contains few impurities is preferred. For example, 99.99 mass % Al, 99.96 mass % Al, 99.9 mass % Al, 99.85 mass % Al, 99.7 mass % Al, and 99.5 mass % Al are preferred. Thus, increasing the purity of the aluminum of the Al base 14 makes it possible to avoid occurring intermetallic compounds, which cause deposits, and increase the integrity of the insulation layer 16. In a case where an aluminum alloy is anodized, the possibility exists that intermetallic compounds will become the origin of poor insulation; and this possibility increases as the amount of intermetallic compounds increases.

Especially, when a material with the purity of 99.5 mass %, or 99.99 mass % or more is used as the Al base 14, disturbance of the regular formation (hereinafter referred also to as regularization) of the micropore of the anodized film described later is controlled, thus the above material is preferred Disturbance of the regularization of anodized film can provide a starting point for cracks when a thermal strain is applied. For this reason, the Al base 14 has higher heat resistance when the purity is higher.

Further, as described above, more cost effective industrial aluminum can also be used for the Al base 14. However, in terms of insulation properties of the insulation layer 16, it is preferable for Si not to precipitate out in the Al base 14.

In the substrate 10, the insulation layer 16 is for electrical insulation and for preventing damage from mechanical impact during handling. This insulation layer 16 is made of an anodized film (alumina film, Al₂O₃ film) formed by anodization of aluminum.

The anodized film which forms the insulation layer 16 has compressive strain (strain in the direction of compression C) at room temperature (23 degree C.), and the magnitude of this strain is 0.005-0.25%. Normally, tensile strain exists in an anodized film of aluminum.

If compressive strain is less than 0.005%, although there is compressive strain, almost no substantial compressive force acts on the anodized film serving as the insulation layer 16, and the effect of cracking resistance is not readily obtained. On the other hand, the upper limit of compressive strain is 0.25%, considering that cracks are generated, the anodized film bulges up, its flatness decreases and delamination occurs due to the anodized film serving as the insulation layer 16 delaminating and strong compressive strain being applied to the anodized film. It is more preferably 0.20% or less, and particularly preferably 0.15% or less.

Since the past, in a metal substrate with an insulation layer in which an anodized film is formed on the metal substrate as an insulation layer, the topics of concern have been heat resistance during the manufacture of semiconductor elements, bending resistance as a flexible substrate during roll-to-roll manufacturing, and long-term durability and strength.

The problem of heat resistance is caused by the fact that when exposed to high temperature, the anodized film cannot withstand elongation of the metal substrate, and the anodized film ends up fracturing. This is due to the large difference in thermal expansion coefficient between the metal substrate and the anodized film.

For example, in the case of aluminum, the thermal expansion coefficient is 23 ppm/K, and the thermal expansion coefficient of the anodized film is 4-5 ppm/K. For this reason, at high temperatures which bring out a difference in the amount of elongation due to the difference in thermal expansion coefficients, tensile force ends up acting on the anodized film to the extent that it cannot withstand the elongation of the base metal, and the anodized film fractures.

The problem of bending resistance is caused by the fact that the anodized film cannot withstand the tensile stress incurred and the anodized film ends up fracturing when the anodized film is bent to the outside.

The problem of durability and strength is caused by the fact that the anodized film cannot withstand changes in stress accompanying interference as described below, and the anodized film ends up fracturing. Specific examples of interference are stress accompanying changes in volume and degradation of the anodized film, semiconductor layer, sealing layer and so forth accompanying thermal expansion or compression, external stress, humidity, temperature and oxidation of the substrate due to rising and falling temperature accompanying start and stop of operation incurred by the anodized film over the long term.

As a result of diligent research, the inventors discovered that by providing the anodized film with compressive strain at room temperature, it is possible to realize an anodized film having heat resistance during the manufacture of semiconductor elements, bending resistance as a flexible substrate during roll-to-roll manufacturing, and long-term durability and strength.

The reasons that cracking resistance is improved by providing the anodized film with compressive strain at room temperature can be explained as follows. Here, the mechanism of improvement of heat-resistant cracking resistance is described as an example, but it is estimated that the same mechanism is at work in the improvement of cracking resistance against the external stresses of bending and temperature changes, in that fracture of the anodized film by tensile force is inhibited.

As described above, anodized films according to prior art have internal tensile strain of about 0.005-0.06% at room temperature. Further, since the linear thermal expansion coefficient of the anodized film is about 5 ppm/K and the linear thermal expansion coefficient of aluminum is 23 ppm/K, the tensile strain acts on the anodized film in a proportion of 18 ppm/K due to a rise in temperature in the case of an anodized film on an aluminum substrate. When tensile strain of 0.16-0.23% is applied, which is the fracture limit of the anodized film, cracks are generated. This temperature is 120-150 degree C. in anodized films according to prior art.

On the other hand, the anodized film in the present invention has internal compressive strain at room temperature. Here, regardless of the type of film, the linear thermal expansion coefficient of an anodized film has been confirmed by the inventors to be about 5 ppm/K, and it is about 5 ppm/K for the anodized film in the present invention as well. Therefore, tensile strain acts on the anodized film in a proportion of 18 ppm/K due to a temperature increase. The fracture limit of an anodized film is estimated to be about 0.16-0.23% regardless of the type of film, and it is believed that when tensile strain of this magnitude is applied, cracks are generated.

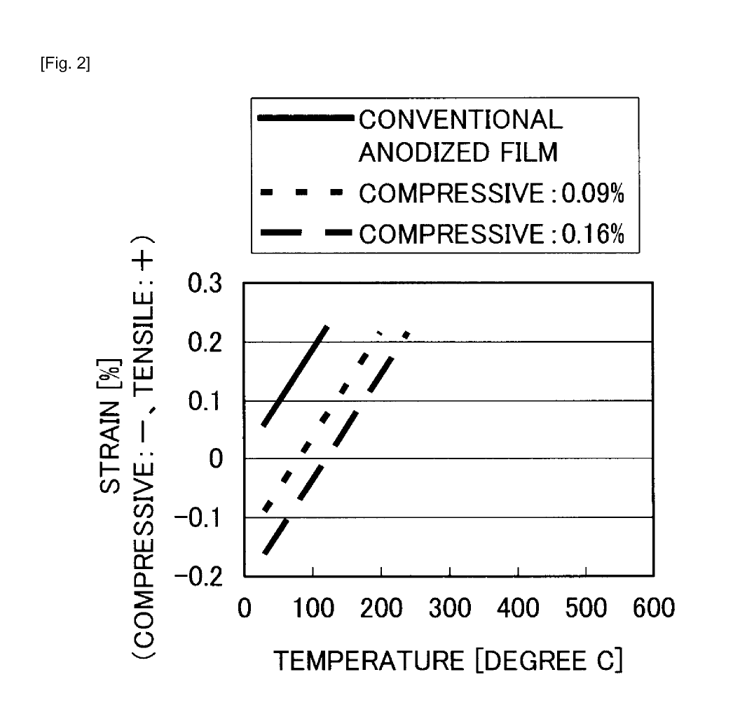

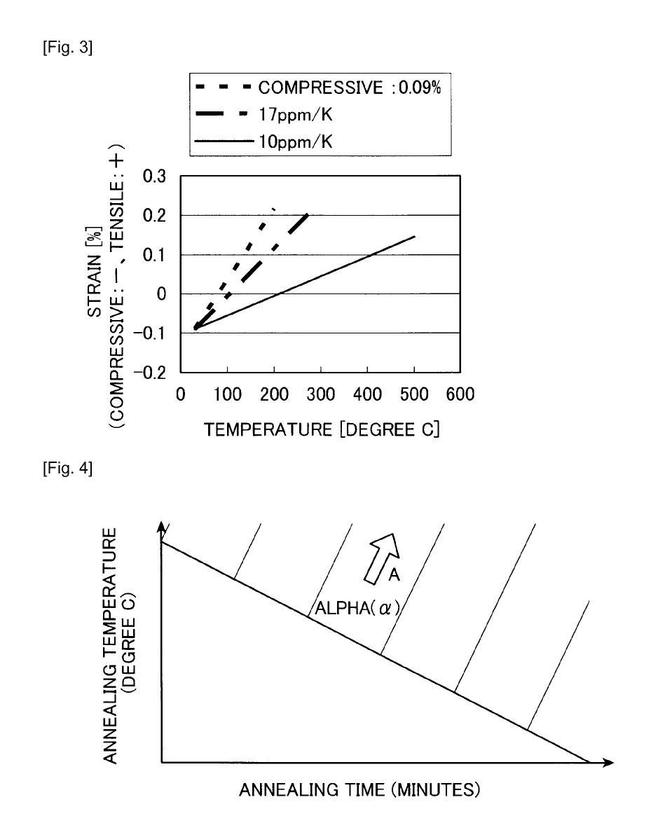

In the case of an anodized film having compressive strain in the preferred range of 0.005-0.25% at room temperature, if it is assumed that tensile strain is applied in a proportion of 18 ppm/K, then tensile strain of 0.16-0.23% is applied at 170-340 degree C. FIG. 2 schematically illustrates the tensile strain applied to the anodized film in the cases where the compressive strain is 0.09% and 0.16%, and a conventional anodized film. As illustrated in FIG. 2, the crack generation temperature can be further increased by increasing the amount of compressive strain. Actually, although not completely consistent with model calculations, it has been confirmed empirically that the crack generation temperature can be increased, due to primary factors such as the fact that the linear thermal expansion coefficient of an anodized film is not necessarily constant, the fact that there is shrinkage accompanying dehydration of moisture contained in an anodized film and the fact that rigidity of the substrate is lost following softening of aluminum.

Further, the crack generation temperature can be further increased by using a composite substrate of aluminum and a different metal as the substrate. The linear thermal expansion coefficient of the composite substrate can be determined as an average value according to the linear expansion coefficients, Young's moduli and thicknesses of the constituent metal materials. If a composite substrate of aluminum and a metal material having a linear thermal expansion coefficient lower than that of aluminum (23 ppm/K) and greater than or equal to that of the anodized film (5 ppm/K) is used, the linear thermal expansion coefficient of the composite substrate can be made lower than 23 ppm/K, although it also depends on Young's modulus and thickness. FIG. 3 schematically illustrates the tensile strain applied to the anodized film in the cases where the linear thermal expansion coefficient of the composite substrate is 17 ppm/K and 10 ppm/K. Even with an anodized film having the same compressive strain at room temperature, the crack generation temperature can be further increased by reducing the linear thermal expansion coefficient of the substrate. Actually, although not completely consistent with model calculations, it has been confirmed empirically that the crack generation temperature can be further increased, due to primary factors such as the fact that the linear thermal expansion coefficient of an anodized film is not necessarily constant and the fact that there is accompanying dehydration of moisture contained in an anodized film.

The anodized film having a compressive strain at room temperature can be obtained using methods such as one specifically described below. It should of course be understood that it is not limited to these methods.

One method to provide a compressive strain is to anodize the Al base of a metal substrate under a condition that the metal substrate is extended further than its state of usage at room temperature. It is not especially limited as long as, for example, a tensile force can be applied in the tensile direction within the range of elastic deformation or curvature can be kept imparted. For example, when the roll-to-roll process is used, tension during transport is adjusted to provide a tensile force to the metallic substrate 15, or curvature is imparted to the metallic substrate 15 with the shape of a transport path in an anodizing tub as a curved surface. Anodic treatment performed under such a condition provides an anodized film with the magnitude of the compressive strain at room temperature (23 degree C.) of 0.005-0.25%. In this method, the whole anodized film has a compressive strain. That is, both the barrier layer and the porous layer have a compressive strain. This phenomenon was discovered by the inventors while pursuing research of anodized aluminum.

The following method can also be used. Using an aqueous solution with the temperature of 50-98 degree C., a metal substrate is anodized under a condition that it is extended further than its state of usage at room temperature, so that when it is returned to the room temperature the compressive strain is applied to the anodized film. In this method, since the temperature of the aqueous solution used for anodization is at most approximately 100 degree C., the extension of the metal substrate is at most 0.1%. Therefore, the compressive strain of the anodized film will also be 0.1%. Therefore, when the compressive strain is applied to the anodized film using the aqueous solution at the temperature of 50-98 degree C., the compressive strain is at most approximately 0.1%. In this method, the whole anodized film has a compressive strain. That is, both the barrier layer and the porous layer have a compressive strain. This phenomenon was discovered by the inventors while pursuing research of anodized aluminum.

Further, the following method can also be used. By annealing the aluminum material that forms the anodized film by raising the temperature to an extent such that the anodized film does not break, when returned to room temperature, it changes to a state where compressive strain acts on the anodized film. The anodized film that is extended at a high temperature experiences a structural change to ease the tensile strain, and the compressive strain is generated in the anodized film in conjunction with shrinkage of the aluminum material when the temperature drops. Thus, with the anodized film kept as it was produced, the whole of the anodized film with a tensile strain can be changed to have a compressive strain. That is, a strain of both the barrier layer and the porous layer change to a compressive strain. Hereafter, the effect of thus changing a tensile strain into a compressive strain is referred to as a compression effect. This phenomenon was discovered by the inventors while pursuing research of anodized aluminum.

The compression effect can be easily discovered in the area alpha as schematically illustrated in FIG. 4, and in this area alpha, the compression effect becomes larger as the area goes in the direction of the arrow head A. Thus, in annealing treatment, the higher the temperature is and the longer it takes, the larger the compression effect will be. This has also been confirmed by the inventors.

The compression effect of the anodized film by this annealing can be obtained regardless of anodization conditions. Thus, electrolytic solution used for anodization includes aqueous electrolytic solution such as an inorganic acid, organic acid, alkali, buffer solution, and combination thereof, and non-aqueous electrolytic solution such as an organic solvent and molten salt. Further, the structure of the anodized film can be controlled by the density, voltage, temperature, etc., of the electrolytic solution; however, in any anodized film, a tensile strain produced in the anodized film by annealing can be changed to a compressive strain.

Furthermore, it has been confirmed that a similar compression effect of changing the strain of the anodized film to compressive strain is obtained whether the atmosphere of annealing is vacuum or air at atmospheric pressure.

The present invention indicates an anodized film applied with a compressive strain; however, the strain and stress are in a linear relation in the elasticity range with the Young's modulus of the material as a multiplier, thus an anodized film applied with compressive stress is a synonymous. The inventors have confirmed that the Young's modulus of the anodized film is 50 GPa to 150 GPa. The range of preferable compressive stress is shown below from this value and the range of the above-mentioned preferable compressive strain.

In the substrate 10, the insulation layer 16 is applied with stress in the compression direction (hereinafter referred to as compressive stress) at room temperature and the magnitude of the compressive stress is 2.5 MPa to 300 MPa. The magnitude of the compressive stress is preferably 5 MPa to 300 MPa, more preferably 5 MPa to 150 MPa, and especially preferably 5 MPa to 75 MPa.

When the compressive stresses is less than 2.5 MPa, the compressive stress is not substantially applied to the anodized film used as the insulation layer 16, and the effectiveness of cracking resistance is difficult to obtain. On the other hand, the upper limit of the compressive stress is 300 MPa considering the anodized film used as the insulation layer 16 coming off, and cracks being formed on the anodized film.

Further, as described above, when the aqueous solution with the temperature of 50-98 degree C. is used to apply a compressive strain to the anodized film under a condition that the metal substrate is extended further than its state of usage at room temperature, it is difficult to provide a large compressive strain. For this reason, the upper limit is approximately 150 MPa.

In the substrate 10, the thickness of the insulation layer 16 is preferably at least 3 micrometers and at most 20 micrometers, more preferably at least 5 micrometers and at most 20 micrometers, and particularly preferably at least 5 micrometers and at most 15 micrometers. An excessively large thickness of the insulation layer 16 reduces its flexibility and increases the cost and time required for formation thereof, and is thus not preferred. Further, if the insulation layer 16 is extremely thin, there is risk that it will be incapable of electrical insulation and preventing damage from mechanical impact during handling.

The front surface 18a of the insulation layer 16 has a surface roughness in terms of, for example, arithmetic mean roughness Ra is 1 micrometer or less, preferably 0.5 micrometers or less, and more preferably 0.1 micrometers or less.

The substrate 10 includes the metal base 12, the Al base 14, and the insulation layer 16 which are all made of flexible materials, and is therefore flexible as a whole. Thus, on the insulation layer 16 side of the substrate 10, a semiconductor element, a photoelectric conversion element, or the like can be formed by the roll-to-roll process for example.

Further, although the substrate 10 in this embodiment has a structure with the Al base 14 and the insulation layer 16 formed on both sides of the metal base 12, in the present invention, as shown in FIG. 1B, the Al base 14 and the insulation layer 16 may be formed only on one side of the metal base 12. Thus, the substrate 10a can be thinner and lower in cost by using the metallic substrate 15a having the two-layer clad structure of the metal base 12 of stainless steel and the Al base 14.

Furthermore, in this embodiment, although the metallic substrate 15 has the two-layer structure of the metal base 12 and the Al base 14, in the present invention, since there should only be the Al base 14, the metal base 12 may be formed of the same Al base as the Al base 14; therefore, the metal substrate may be formed only of the Al base, and as the shown with the substrate 10b illustrated in FIG. 1C, the metallic substrate 15b may be formed only of the Al base 14. The metal bases 12 of the metal substrates 15 and 15a may have two or more layers.

Next, the method of measuring the strain of the anodized film serving as the insulation layer 16 is described.

Note that below, strain of the anodized film is, strictly speaking, the combination of the strain of the porous layer and the strain of the barrier layer, and from the formulas of materials dynamics, it is a weighted average which takes into account the Young's modulus and film thickness of both. However, there is no problem if the strain below is considered to be the strain of the porous layer. Here, since the porous layer and the barrier layer are the same compound having only different structures, their Young's moduli are assumed to be the same. Therefore, the strain of the anodized film is considered to be a weighted average which takes into account film thickness with respect to the strain of the porous layer and the strain of the barrier layer. The thickness of the barrier layer is known to be the thickness obtained by multiplying the anodization voltage by a coefficient of about 1.4 nm/V, and at most about several hundred nm. Therefore, the porous layer is normally several times thicker to several tens of times thicker than the barrier layer. If the thickness of the porous layer is at least 3 micrometers, as is preferred in the present invention, it is at least 10 times as thick. For this reason, the effect of the strain of the barrier layer is almost unnoticed in the strain of the anodized film as a whole. Therefore, the strain of the anodized film measured by the technique below is considered to be the strain of the porous layer.

In the present invention, the length of the anodized film is first measured in the state of the substrate 10.

Next, the metallic substrate 15 is dissolved and removed, and the anodized film is taken from the substrate 10. Then, the length of the anodized film is measured.

The strain is determined from this length before and after removal of the metallic substrate 15.

When the length of anodized film is longer after the metallic substrate 15 is removed, the compression force is applied to the anodized film. That is, the compressive strain is applied to the anodized film. On the other hand, when the length of the anodized film is shorter after the metallic substrate 15 is removed, the tensile force is applied to the anodized film. That is, the strain in the tensile direction is applied to the anodized film.

Note that the length of the anodized film before and after removal of the metallic substrate 15 may be the length of the entire anodized film or the length of a portion of the anodized film.

In a case where the metallic substrate 15 is dissolved, the solution used may be a copper chloride hydrochloric acid aqueous solution, a mercury chloride hydrochloric acid aqueous solution, a tin chloride hydrochloric acid aqueous solution, an iodine methanol solution, etc. The solution for dissolving is appropriately selected in accordance with the composition of the metallic substrate 15.

In the present invention, in addition to removal of the metallic substrate 15, the warpage and deflection of a metal base having a high planarity for example, are measured, an anodized film is formed on only one side of the metal base, and then the warpage and deflection of the metal base after formation of the anodized film are measured. The warpage and deflection values before and after formation of the anodized film are then used to obtain the strain.

The warpage and deflection of the metal base are measured using, for example, an optically precise measurement method employing a laser. Specifically, the various measurement methods described in the “Journal of the Surface Finishing Society of Japan,” 58, 213 (2007), and in “R&D Review of Toyota CRDL” 34, 19 (1999) may be used to measure the warpage and deflection of the metal base.

The strain of the anodized film serving as the insulation layer 16 may be measured as described below. In this case, the length of the thin film of aluminum is measured first. Next, the anodized film is formed on the thin film of the aluminum, and the length of the thin film of the aluminum at this time is measured. The shrinkage is calculated from the length of the thin film of the aluminum before and after the anodized film is formed, and is converted into the strain.

Note that, since all of the methods measure the strain of the anodized film with the metallic substrate 15 remained except for the method to remove the metallic substrate 15, it is difficult to say that the influence of the metallic substrate 15 can be completely removed. Therefore, if the method to remove the metallic substrate 15 is used, the strain of the anodized film itself can be directly measured without any influence of the metallic substrate 15. Therefore, in the measurement of the strain according to the present invention, a method that removes the metallic substrate 15 is preferred for accurately measuring the strain of the anodized film.

Further, the internal stress of the anodized film can be calculated with the formula of material mechanics using the Young's modulus of the anodized film and the strain that exists in the anodized film. The strain can be calculated as described above.

On the other hand, the Young's modulus of the anodized film can be found by conducting an indentation test or a push-in test using a nanoindenter, etc, on the anodized film in the substrate 10 as is.

In addition, the Young's modulus of the anodized film can be found by removing the metallic substrate 15 from the substrate 10, removing the anodized film, and then conducting an indentation test on the removed anodized film using the push-in tester or nanoindenter, etc.

Further, the Young's modulus of the anodized film can be found by conducting a tensile test on or measuring the dynamic viscoelasticity of either a sample in which a thin metallic film such as aluminum was formed on the anodized film, or the anodized film singly remove from the substrate 10.

Note that measuring the Young's modulus of a thin film using the indention test may adversely affect the metallic substrate 15, and thus the indentation depth generally needs to be suppressed to within about one-third of the thickness of the thin film. For this reason, to accurately measure the Young's modulus of the anodized film having the thickness of about several tens of micrometers, measurement using a nanoindenter which is capable of measuring the Young's modulus and hardness even with an indentation depth of a few hundred nanometers is preferred.

Needless to say, the Young's modulus may be measured using methods other than the one described above.

Next, the production method of the substrate 10 of this embodiment will be described.

First, the metal base 12 is prepared. This metal base 12 is formed to a predetermined shape and size suitable to the size of the substrate 10 to be formed.

Then, the Al base 14 is formed on the front surface 12a and on the back surface 12b of the metal base 12. The metallic substrate 15 is thus formed.

The method of forming the Al base 14 on the front surface 12a and on the back surface 12b of the metal base 12 is not particularly limited, provided that an integral bond that can assure adhesion between the steel base 12 and the aluminum base 14 is achieved. As the formation method of the aluminum base 14, for example, vapor-phase methods such as vapor deposition or sputtering, plating, and pressure welding (pressurizing and bonding) after surface cleaning may be used. Pressure-bonding by rolling or the like is the preferred method of forming the aluminum base 14 in terms of cost and mass producibility. For example, when an Al base with the thickness of 50 micrometer is cladded to the metal base 12 of stainless steel with the thickness of 150 micrometer by pressure welding to form the metallic substrate 15, the obtained metallic substrate 15 can have the linear thermal expansion coefficient of as low as approximately 10 ppm/K.

Next, the metallic substrate 15 is extended, and the anodized film serving as the insulation layer 16 is formed on the front surface 14a and the back surface 12b of the Al base 14 of the metallic substrate 15 in this state. The method of forming the anodized film serving as the insulation layer 16 is described below.

Anodization treatment can be performed using, for example, a known anodization apparatus of so-called roll-to-roll process type.

The anodized film serving as the insulation layer 16 can be formed by immersing the metal base 12 serving as the anode in an electrolytic solution together with the cathode and applying voltage between the anode and the cathode. In the case, the metal base 12 forms a local cell with the Al base 14 upon contact with the electrolytic solution, and therefore the metal base 12 contacting the electrolytic solution is to be masked and isolated using a masking film (not shown). That is, the end surface and the back surface of the metal base 15 other than the front surface 14a of the Al base 14 need to be isolated using a masking film (not shown). Note that the method of masking during the anodization treatment is not limited to the use of masking film. Possible masking methods include, for example, a method in which the end surfaces and the back surface of the metallic substrate 15 other than the surface 14a of the Al base 14 are protected using a jig, a method in which water-tightness is ensured using rubber, and a method in which the surfaces are protected using resist material.

Where necessary, pre-anodization may include steps of subjecting the surface 14a of the Al base 14 to cleaning and polishing/smoothing processes.

Anodization treatment may also be performed in the state where the metallic substrate 15 is extended more than in the state of use at room temperature. For example, the method of extending the metallic substrate 15 more than in the state of use at room temperature is not particularly limited as long as it results in the state where tensile force is provided in the tensile direction E (refer to FIG. 1A) within the range of elastic deformation, or in the state where curvature has been provided. For example, if a roll to roll process is used, the metallic substrate 15 is provided with tensile force by adjusting the tension during transport, or the metallic substrate 15 is provided with curvature by using a curved surface as the shape of the transport path in the anodizing tank. By performing anodization treatment in this state, an anodized film having compressive strain at room temperature (23 degree C.) of 0.005-0.25% can be obtained. In this case, the magnitude of the compressive stress that acts on the anodized film is 2.5-300 MPa.

Note that the state of use at room temperature is the state of the metal substrate at room temperature in the case where the substrate 10 is used as an end product of a semiconductor device, thin-film solar cell or the like.

After anodization treatment, the substrate 10 described above can be obtained by peeling off the masking film (not shown).

Further, in the case of single wafer processing, it is preferred that anodization treatment is performed in the state where the metallic substrate 15 has been extended by affixing it to the anodization tank using a jig.

Anodization treatment may also be performed by methods performed in the past in this field. Exemplary electrolytic solutions used for anodization include an aqueous electrolytic solution such as an inorganic acid, organic acid, alkali, buffer solution, or combination thereof, and a non-aqueous electrolytic solution such as an organic solvent or molten salt. Specifically, an anodized film can be formed on the surface 14a of the Al base 14 by introducing direct current or alternating current to the Al base 14 in an aqueous solution or non-aqueous solution of an acidic solution of sulfuric acid, oxalic acid, chromic acid, formic acid, phosphoric acid, malonic acid, diglycolic acid, maleic acid, citraconic acid, acetylenedicarboxylic acid, malic acid, tartaric acid, citric acid, glyoxalic acid, phthalic acid, trimellitic acid, pyromellitic acid, sulfamic acid, benzene sulfonic acid, or amide sulfonic acid, or a combination of two or more thereof. Carbon or aluminum is used for the cathode during anodization.

Further, an alkali solution other than the acidic solutions described above may be used in anodization treatment. Examples of alkali solutions include sodium hydroxide, ammonium hydroxide and sodium phosphate. Additionally, a nonaqueous may be used in the anodization treatment. As a nonaqueous a formamide-boric acid bath, an NMF (N-methylformamide)-boric acid bath, an ethanol-tartaric acid bath, DMSO (dimethyl sulfoxide)-salicylic acid bath or the like may be used. Note that an NMF-boric acid bath is an electrolytic solution in which boric acid is dissolved in N-methylformamide.

During the anodization treatment, an oxidation reaction proceeds substantially in the vertical direction from the front surface 14a of each of the Al base 14 to form the anodized film on the front surface 14a of each of the Al base 14. The anodized film is of a porous type in which a large number of fine columns in the shape of a substantially regular hexagon as seen from above are densely arranged, a micropore having a rounded bottom is formed at the core of each fine column, and at the bottom of each fine column having a barrier layer with a thickness of typically 0.02-0.1 micrometers is formed.

The anodized film having such a porous structure has a low Young's modulus compared to a simple aluminum oxide film of a non-porous structure, higher bending resistance, and higher resistance to cracking due to a difference in thermal expansion when heated.

Further, other than performing anodization treatment in a state where the metallic substrate 15 is physically elongated more than in the state of use at room temperature as described above, there is also a method of performing anodization in a 50-98 degree C. aqueous solution, which is higher than the temperature of actual use. In this case, the metallic substrate 15 is extended more than in the state of use at room temperature, and anodization can be performed while maintaining the extended state as is.

When anodization is performed in a 50-98 degree C. aqueous solution, the aqueous solution is preferably made from an acid having a pKa (acid dissociation constant) at 25 degree C. of 2.5 to 3.5.

Note that the aqueous solution used for anodization treatment has a boiling point of 100 degree C.+elevation, but performing the anodization treatment at the boiling point of the aqueous solution is not practical, and byproducts (boehmite) are produced to extend the temperature is high. Thus, the upper limit of the temperature of the aqueous solution is 98 degree C., which is lower than the boiling point, and more preferably 95 degree C. or less.

The reason that an aqueous solution comprising an acid whose pKa at 25 degree C. is at least 2.5 can be explained by the relationship to the rate of dissolution of the anodized film by the acid. The pKa, that is, the strength of the acid is known to be somewhat correlated with the dissolution speed of the anodized film [as described in the Journal of the Surface Finishing Society of Japan, 20, 506, (1969), for example]. The actual growth of the anodized film is a complex reaction that proceeds as generation of the anodized film by an electrochemical reaction and dissolution of the anodized film by acid simultaneously occur, making the rate of dissolution of the anodized film a primary cause of film formation.

When the pKa is less than 2.5, the rate of dissolution at a high temperature is too high compared to the generation of the anodized film, sometimes causing failure to achieve stable growth of the anodized film and formation of a relatively thin film that reaches the critical film thickness, resulting in an inadequate anodized film serving as the insulation layer.

On the other hand, an aqueous solution comprising an acid whose pKa at 25 degree C. is 3.5 or less is preferred, and that whose pKa is 3.0 or less is even more preferred. When the pKa at 25 degree C. exceeds 3.5, the rate of dissolution is too slow even at a high temperature compared to the generation of the anodized film, sometimes causing formation of the anodized film to be extremely time consuming and failure to form a thick film due to formation of an anodized film called the barrier type, resulting in an inadequate anodized film serving as an insulation layer.

Unlike the porous-type anodized film of the present invention, the barrier-type anodized film has a dense structure. Its thickness is known to be nearly proportional to the anodization voltage. If anodization is performed with a voltage exceeding 1000 V, insulation breakdown occurs during anodization, and therefore it is difficult to obtain an anodized film whose thickness exceeds 2 micrometers, and it is difficult to maintain insulation properties in air. Further, since it is a dense film, fracture tends to occur when stress is incurred, and cracking resistance is low compared to the porous type anodized film.

Acids having a pKa (acid dissociation constant) of 2.5 to 3.5 include, for example, malonic acid (2.60), diglycol acid (3.0), malic acid (3.23), tartaric acid (2.87), and citric acid (2.90). The solution used for anodization may be a mixed solution of such acids having a pKa (acid dissociation constant) of 2.5 to 3.5, other acids, bases, salts, and additives.

If anodization is performed by a carboxylic acid having a pKa of 2.5-3.5, carboxylic acid anions (called acid radicals) are contained in the anodized film, and an anodized film which includes carbon is formed.

In this embodiment, by performing anodization treatment on the metallic substrate 15 using a 50-98 degree C. acidic aqueous solution having a pH at 25 degree C. of 2.5-3.5, it is possible to obtain an anodized film having compressive strain of 0.005-0.1% at room temperature (23 degree C.).

In this case, the magnitude of the compressive stress that acts on the anodized film is 2.5-150 MPa.

After anodization treatment, the substrate 10 described above can be obtained by peeling off the masking film (not shown).

The preferred thickness of the anodized film serving as the insulation layer 16 is 3-20 micrometers, more preferably 5-20 micrometers, and particularly preferably 5-15 micrometers.

The thickness can be controlled by the electrolysis time and the magnitude of the current or voltage in constant current electrolysis or constant voltage electrolysis.

Note that a dense anodized film (non-porous aluminum oxide single film), rather than an anodized film in which porous fine columns are arranged, is obtained by electrolytic treatment in a neutral electrolytic solution such as boric acid. After the porous anodized film is formed in the acidic electrolytic solution, an anodized film in which the thickness of the barrier layer is increased may be formed by a pore filling method that subjects the film to electrolytic treatment once again in a neutral electrolytic solution. The film can have higher insulation properties by increasing the thickness of the barrier layer.

A boric acid aqueous solution is preferred as the electrolytic solution used in the pore filling process, and an aqueous solution obtained by adding a borate containing sodium to boric acid aqueous solution is even more preferred. Examples of borates include disodium octaborate, sodium tetraphenylborate, sodium tetrafluoroborate, sodium peroxoborate, sodium tetraborate, sodium metaborate and so forth. The borates may be procured as anhydrides or hydrates.

A particularly preferred electrolytic solution used in pore filling is an aqueous solution obtained by adding 0.01-0.5 mol/L sodium tetraborate to 0.1-2 mol/L boric acid aqueous solution. It is preferred that aluminum ions are dissolved in an amount of 0-0.1 mol/L. Aluminum ions may be dissolved chemically or electrochemically by pore filling treatment in an electrolytic solution, but a particularly preferred method is electrolysis after adding aluminum borate in advance. Also, trace elements contained in the aluminum alloy may be dissolved.

In this embodiment, in the anodized film having a porous structure, the micropores may be formed regularly, that is, it may be a regularized porous structure.

In the anodized film have a porous structure, forming the micropores in a regular manner may be performed by an anodization treatment called self regularization, described below.

Self regularization is a method by which regularity is improved by eliminating causes of disturbance of a regular array using the property that the micropores of an anodized film align in a regular manner. Specifically, an anodized film is formed at a low rate over a long period (for example, several hours to ten-plus hours) using high-purity aluminum at a voltage corresponding to the type of electrolytic solution, after which film removal treatment is performed.

In self regularization, since the micropore diameter depends on the applied voltage, the desired micropore diameter can be obtained to a certain degree by controlling the applied voltage.

As typical examples of self regularization, J. Electrochem. Soc., Vol. 144, No. 5, May 1997, p. L128, and Jpn. J. Appl. Phys., Vol. 35 (1996), Pt. 2, No. 1B, L126, and Appl. Phys. Lett., Vol. 71, No. 19, 10, November 1997, p. 2771 are known.

Further, in the method described in this public literature, the film removal treatment that removes the anodized film by dissolving takes at least 12 hours using a 50 degree C. mixed aqueous solution of chromic acid and phosphoric acid. Note that when treated using a boiling aqueous solution, the origin of regularization is destroyed and disturbed, and therefore it is used without being boiled.

In an anodized film in which the micropores are regularly formed, the degree of regularity increases nearer the aluminum portion, and therefore, once the film is removed, the bottom portion of the anodized film that remains on the aluminum portion comes to the surface, and regular dents are obtained. Therefore, in the film removal treatment, only the aluminum oxide anodized film is dissolved, without the aluminum being dissolved.

As a result, in the methods stated in this known literature, although there are various micropore diameters, the irregularity (coefficient of variation) of the micropore diameter is 3% or less.

For example, as an anodization treatment by self ordering method, a method may be used wherein electricity is passed through an aluminum member serving as an anode in a solution having an acid concentration of 1-10 mass %. As the solution used in anodization treatment, one or more kinds of acids such as sulfuric acid, phosphoric acid, chromic acid, oxalic acid, sulfamic acid, benzenesulfonic acid, amidosulfonic acid and the like may be used.

After the anodization treatment, the metallic substrate 15 in which the anodized film serving as the insulation layer 16 was formed is annealed. By so doing, a substrate 10 in which the insulation layer 16 has been provided with 0.005-0.25% compressive strain can be formed.

Note that annealing treatment is performed on the anodized film at a temperature of 600 degree C. or below. Further, the annealing treatment is preferably performed under conditions of a heating temperature of 100-600 degree C. and a holding time of 1 second to 100 hours. In this case, the heating temperature of the annealing treatment is at or below the softening temperature of the Al base 14. A predetermined compressive strain can be achieved by changing the annealing conditions. As described above, as illustrated in FIG. 4, the compressive strain of the anodized film can be increased by increasing the heating temperature and increasing the holding time of annealing.

An annealing heating temperature of less than 100 degree C. fails to substantially achieve a compression effect. On the other hand, if the annealing heating temperature exceeds 600 degree C., there is the risk that the anodized film will break due to the difference in thermal expansion coefficients between the metal substrate and anodized film. Thus, annealing must be performed at a temperature such that the anodized film does not fracture. If an aluminum material is used in the metal substrate, softening of the aluminum becomes excessive as the temperature increases, and there is risk of causing deformation of the base. Therefore, it is preferably 300 degree C. or below, more preferably 200 degree C. or below, and particularly preferably 150 degree C. or below. On the other hand, if a metal substrate is used, in which an aluminum base is provided on at least one surface of a metal base made of a metal different from aluminum, intermetallic compounds are formed at the interface between the aluminum and metal base as the temperature increases, and if it is excessive, there is risk of delamination of the interface. Therefore, it is preferably 500 degree C. or below, more preferably 400 degree C. or below, and particularly preferably 300 degree C. or below.

Further, the annealing holding time is at least 1 second in order to achieve a compression effect, albeit slight. On the other hand, even if the annealing holding time exceeds 100 hours, the compression effect becomes saturated, and thus the upper limit is 100 hours.

If an aluminum material is used in the metallic substrate, softening and creep of the aluminum become excessive as the time gets longer, and there is risk of causing deformation of the base. In terms of productivity as well, it is preferably 50 hours or less, more preferably 10 hours or less, and particularly preferably 1 hour or less. On the other hand, if a metal substrate is used, in which an aluminum base is provided on at least one surface of a metal base made of a metal different from aluminum, intermetallic compounds are formed at the interface between the aluminum and metal base as the time gets longer, and if it is excessive, there is risk of delamination of the interface. In terms of productivity as well, it is preferably 10 hours or less, more preferably 2 hours or less, and particularly preferably 30 minutes or less.

Note that, as illustrated in FIG. 1C, if the metallic substrate 15b in the substrate 10 is constructed of a single Al base 12, if the heating temperature of the Al base 12 exceeds the softening temperature, the anodized film ends up dominating the amount of elongation of the substrate, and the metal substrate does not elongate. For this reason, it is difficult to obtain a compression effect, and it cannot be maintained at a constant strength. Thus, if the metal substrate is a single Al base, the heating temperature of the annealing treatment may be at or below the softening temperature of the Al base 12.

In the substrate 10 of this embodiment, the internal stress of the anodized film at room temperature is in a compressive state, and the magnitude of its strain is 0.005-0.25%, and since compressive strain acts on the anodized film of the insulation layer 16, it makes it difficult for cracking to occur, and cracking resistance is excellent. A metal substrate with an insulation layer can be obtained.

Moreover, the substrate 10 uses an anodized aluminum film as the insulation layer 16. Since this anodized aluminum film is ceramic, chemical changes do not readily occur at high temperatures, enabling use of the anodized aluminum film as an insulation layer 16 that offers high reliability without cracking. For this reason, the substrate 10 can be used as a heat-resistant substrate that is strong against thermal strain.

Further, in the substrate 10, the anodized film of the insulation layer 16 is changed to a state of compressive strain at room temperature, making it difficult for cracks to be generated even if the film experiences start-to-finish production in a roll-to-roll process, and imparting the film with resistance to bending strain.

Note that when tensile strain acts on it at room temperature, once breaking or cracking occurs, that tensile force acts to open up that break or crack, leaving the break or crack in an open state. As a result, the substrate can no longer maintain electrical insulation properties.

When the substrate 10 is used in a solar cell or the like, long-term reliability of insulation properties can be obtained even if the solar cell is placed outdoors and defects are generated in the anodized film of the insulation layer 16 or the Al base 14 due to extreme temperature changes, external impact or time-dependent change.

Further, if the substrate 10 is exposed to a high-temperature environment of, for example, 500 degree C. or above, defects such as breaks and cracks do not occur because the tensile stress incurred by the anodized film due to the difference in thermal expansion coefficients between the anodized film of the insulation layer 16 and the metallic substrate 15 is mitigated by elongation of the metallic substrate 15 in the tensile direction E (refer to FIG. 1A). Improvement of the heating temperature resistance may be thus obtained. In this way, a substrate 10 that does not have performance degradation even when exposed to a high-temperature environment of 500 degree C. or above can be obtained. For this reason, the photoelectric conversion layer can be formed at even higher temperatures, and a highly efficient thin-film solar cell can be manufactured.

Further, use of the substrate 10 makes it possible to manufacture a thin-film solar cell using a roll to roll process, for example, thereby greatly improving productivity.

Further, in the substrate 10, if the metallic substrate 15 has a two-layer clad structure of a stainless steel metal substrate 12 and an Al base 14, the anodized film of the insulation layer 16 is formed only on the front surface 14a of the Al base 14 due to the fact that the stainless steel metal substrate 12 is protected during the anodization treatment, and the stainless steel material is bare on the back surface of the metallic substrate 15. However, by annealing treatment in an air atmosphere, an iron-based oxide film which is primarily Fe₃O₄ is formed on the bare surface of the stainless steel material. The oxide film functions as a selenium corrosion-proof layer of the stainless steel in cases where selenium is used during deposition of the photoelectric conversion layer of a solar cell, for example. For this reason, it is a substrate that is useful in solar cells that use selenium during deposition of the photoelectric conversion layer.

Next, a thin-film solar cell that uses the metal substrate with an insulation layer of this embodiment is described.

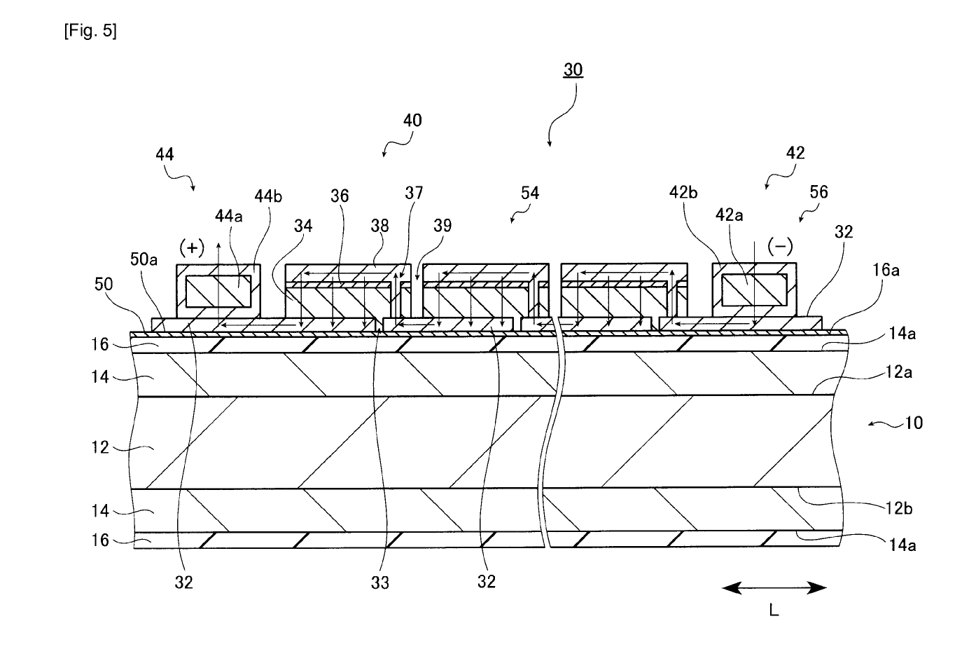

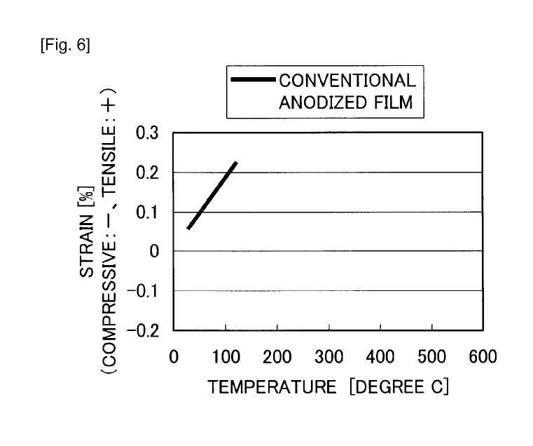

FIG. 5 is a cross section view schematically illustrating a thin-film solar cell using the metal substrate with an insulation layer according to an embodiment of the present invention.

A thin-film solar cell 30 of the embodiment shown in FIG. 5 is used as a solar cell module or a solar cell sub-module constituting this solar cell module, and comprises, for example, a substrate 10 comprising a grounded metallic substrate 15 of substantially rectangular shape and the electrical insulation layer 16 formed on the metallic substrate 15, an alkali supply layer 50 formed on the insulation layer 16, a power generating layer 56 comprising a plurality of power generating cells 54 formed on the alkali supply layer 50 and connected in series, a first conductive member 42 connected to one side of the plurality of the power generating cells 54, and a second conductive member 44 connected to the other side. Note that the body comprising one of the power generating cells (solar cells) 54, the corresponding substrate 10, and the alkali supply layer 50 is herein called a photoelectric conversion element 40, but the thin-film solar cell 30 itself shown in FIG. 5 may be called a photoelectric conversion element.

The thin-film solar cell 30 of this embodiment is formed with the alkali supply layer 50 on the front surface of one of the above-mentioned substrate 10, that is, on the front surface 16a of one insulation layer 16.

The thin-film solar cell 30 includes a plurality of the photoelectric conversion elements 40, the first conductive member 42, and the second conductive member 44.

The photoelectric conversion element 40 makes up the thin-film solar cell 30, and comprises the substrate 10, the alkali supply layer 50, and the power generating cell (solar cell) 54 comprising a back electrodes 32, a photoelectric conversion layers 34, a buffer layer 36, and a transparent electrodes 38.

As described above, the alkali supply layer 50 is formed on the front surface 16a of the insulation layer 16. The back electrodes 32, the photoelectric conversion layers 34, the buffer layers 36, and the transparent electrodes 38 of the power generating cell 54 are layered in that order on a surface 50a of the alkali supply layer 50.

The back electrodes 32 are formed on the surface 50a of the conductive alkali supply layer 50 so as to share a separation groove (P1) 33 with the adjacent back electrodes 32. The photoelectric conversion layer 34 is formed on the back electrodes 32 so as to fill the separation grooves (P1) 33. The buffer layer 36 is formed on the front surface of the photoelectric conversion layer 34. The photoelectric conversion layers 34 and the buffer layers 36 are separated from adjacent photoelectric conversion layers 34 and adjacent buffer layers 36 by grooves (P2) 37 which reach the back electrodes 32. The grooves (P2) 37 are formed in different positions from those of the separation grooves (P1) 33 that separate the back electrodes 32.

The transparent electrode 38 is formed on the surface of the buffer layer 36 so as to fill the grooves (P2) 37.

Opening grooves (P3) 39 are formed so as to reach the back electrodes 32 by penetrating through the transparent electrode 38, the buffer layer 36, and the photoelectric conversion layer 34. In the thin-film solar cell 30, the respective photoelectric conversion elements 40 are electrically connected in series in a longitudinal direction L of the substrate 10 through the back electrodes 32 and the transparent electrodes 38.

The photoelectric conversion elements 40 of this embodiment are so-called integrated photoelectric conversion elements (solar cells), and have a configuration such that, for example, the back electrode 32 is formed of a molybdenum electrode, the photoelectric conversion layer 34 is formed of a semiconductor compound having a photoelectric conversion function such as, for example, a CIGS layer, the buffer layer 36 is formed of CdS, and the transparent electrode 38 is formed of ZnO.

Note that the photoelectric conversion elements 40 are formed so as to extend in the width direction perpendicular to the longitudinal direction L of the substrate 10. Therefore, the back electrodes 32 also extend in the width direction of the substrate 10.

As illustrated in FIG. 5, the first conductive member 42 is connected to the rightmost back electrode 32. The first conductive member 42 is provided to collect the output from the negative electrode as will be described below onto the outside. Although a photoelectric conversion element 40 is formed on the rightmost back electrode 32, that photoelectric conversion element 40 is removed by, for example, laser scribing or mechanical scribing, to expose the back electrode 32.

The first conductive member 42 is, for example, a member in the shape of an elongated strip which extends substantially linearly in the width direction of the substrate 10, and is connected to the rightmost back electrode 32. As shown in FIG. 5, the first conductive member 42 has, for example, a copper ribbon 42a covered with a coating material 42b made of an alloy of indium and copper. The first conductive member 42 is connected to the back electrode 32 by, for example, ultrasonic soldering.

The second conductive member 44 is provided to collect the output from the positive electrode to be described later. Like the first conductive member 42, the second conductive member 44 is a member in the shape of an elongated strip which extends substantially linearly in the width direction of the substrate 10, and is connected to the leftmost back electrode 32. Although a photoelectric conversion element 40 is formed on the leftmost back electrode 32, that photoelectric conversion element 40 is removed by, for example, laser scribing or mechanical scribing, to expose the back electrode 32.

The second conductive member 44 is composed similarly to the first conductive member 42 and has, for example, a copper ribbon 44a covered with a coating material 44b made of an alloy of indium and copper.

The first conductive member 42 and the second conductive member 44 may be formed of a tin-plated copper ribbon. Furthermore, the method of connection of the first conductive member 42 and the second conductive member 44 is not limited to ultrasonic soldering, and they may be connected by such means as, for example, a conductive adhesive or conductive tape.

The photoelectric conversion layer 34 in the photoelectric conversion elements 40 in this embodiment is made of, for example, CIGS, and can be manufactured by a known method of manufacturing CIGS solar cells.

The separation grooves (P1) 33 of the back electrodes 32, the grooves (P2) 37 reaching the back electrodes 32, and the opening grooves (P3) 39 reaching the back electrodes 32 may be formed by laser scribing or mechanical scribing.

In the thin-film solar cell 30, light entering the photoelectric conversion elements 40 from the side of the transparent electrodes 38 passes through the transparent electrodes 38 and the buffer layers 36, and causes the photoelectric conversion layers 34 to generate electromotive force, thus producing a current that flows, for example, from the transparent electrodes 38 to the back electrodes 32. Note that the arrows shown in FIG. 5 indicate the directions of the current, and the direction in which electrons move is opposite to that of current. Therefore, in the photoelectric converters 48, the leftmost back electrode 32 has a positive polarity (plus polarity) and the rightmost back electrode 32 has a negative polarity (minus polarity) in FIG. 5.

In this embodiment, electric power generated in the thin-film solar cell 30 can be output from the thin-film solar cell 30 through the first conductive member 42 and the second conductive member 44.

Also in this embodiment, the first conductive member 42 has a negative polarity, and the second conductive member 44 has a positive polarity. The polarities of the first conductive member 42 and the second conductive member 44 may be reversed; their polarities may vary according to the configuration of the photoelectric conversion elements 40, the configuration of the thin-film solar cell 30, and the like.

In this embodiment, the photoelectric conversion elements 40 are formed so as to be connected in series in the longitudinal direction L of the substrate 10 through the back electrodes 32 and the transparent electrodes 38, but the present invention is not limited thereto. For example, the photoelectric conversion elements 40 may be formed so as to be connected in series in the width direction through the back electrodes 32 and the transparent electrodes 38.

The back electrodes 32 and the transparent electrodes 38 of the photoelectric conversion elements 40 are both provided to collect current generated by the photoelectric conversion layers 34. Both the back electrodes 32 and the transparent electrodes 38 are each made of a conductive material. The transparent electrodes 38 must be have translucency.

The back electrodes 32 are formed, for example, of Mo, Cr, or W, or a combination thereof. The back electrodes 32 may have a single-layer structure or a laminated structure such as a two-layer structure. The back electrodes 32 are preferably formed of Mo.

The back electrodes 32 may be formed by any vapor-phase film deposition method such as electron beam vapor deposition or sputtering.

The back electrodes 32 generally have a thickness of about 800 nm, preferably 200 nm to 600 nm, and more preferably 200 nm to 400 nm. By making the thickness of the back electrodes 32 thinner than standard, it is possible to increase the diffusion speed of the alkali metal from the alkali supply layer 50 to the photoelectric conversion layers 34, as will be described later. Moreover, with this arrangement, the material costs of the back electrodes 32 can be reduced, and the formation speed of the back electrodes 32 can be further increased.

The transparent electrodes 38 are formed, for example, of ZnO doped with Al, B, Ga, Sb etc., ITO (indium tin oxide), SnO₂, or a combination thereof. The transparent electrodes 38 may have a single-layer structure or a laminated structure such as a two-layer structure. The thickness of the transparent electrodes 38, which is not specifically limited, is preferably 0.3-1 micrometers.

The method of forming the transparent electrodes 38 is not particularly limited; they may be formed by coating techniques or vapor-phase film deposition techniques such as electron beam vapor deposition and sputtering.

The buffer layers 36 are provided to protect the photoelectric conversion layers 34 when forming the transparent electrodes 38 and to allow the light impinging on the transparent electrodes 38 to enter the photoelectric conversion layers 34.

The buffer layers 36 is made of, for example, CdS, ZnS, ZnO, ZnMgO, or ZnS (0, OH), or a combination thereof.

The buffer layers 36 preferably have a thickness of 0.03 micrometer to 0.1 micrometer. The buffer layers 36 are formed by, for example, chemical bath deposition (CBD) method.

The photoelectric conversion layer 34 has a photoelectric conversion function, such that it generates current by absorbing light that has reached it through the transparent electrode 38 and the buffer layer 36. In this embodiment, the photoelectric conversion layers 34 are not particularly limited in structure; they are made of, for example, at least one compound semiconductor of a chalcopyrite structure. The photoelectric conversion layers 34 may be made of at least one kind of compound semiconductor composed of a group Ib element, a group IIIb element, and a group VIb element.

For high optical absorbance and high photoelectric conversion efficiency, the photoelectric conversion layers 34 are preferably formed of at least one kind of compound semiconductor composed of at least one kind of group Ib element selected from the group consisting of Cu and Ag, at least one kind of group IIIb element selected from the group consisting of Al, Ga, and In, and at least one kind of group VIb element selected from the group consisting of S, Se, and Te. Examples of the compound semiconductor include CuAlS₂, CuGaS₂, CuInS₂ CuAlSe₂, CuGaSe₂, CuInSe₂ (CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ)Se₂ (CIGS), Cu(In₁₋ₓAlₓ)Se₂, Cu(In₁₋ₓGaₓ) (S, Se)₂, Ag(In₁₋ₓGaₓ)Se₂ and Ag(In₁₋ₓGaₓ) (S, Se)₂.

The photoelectric conversion layers 34 especially preferably contain CuInSe₂(CIS) and/or Cu(In, Ga)Se₂ (CIGS), which is obtained by solid-dissolving (solute) Ga in the former. CIS and CIGS are semiconductors each having a chalcopyrite crystal structure, and reportedly have high optical absorbance and high photoelectric conversion efficiency. Further, CIS and CIGS have less deterioration of the efficiency under exposure to light and exhibit excellent durability.

The photoelectric conversion layer 34 contains impurities for obtaining the desired semiconductor conductivity type. Impurities may be added to the photoelectric conversion layer 34 by diffusion from adjacent layers and/or direct doping into the photoelectric conversion layer 34. There may be a concentration distribution of constituent elements of group I-III-VI semiconductors and/or impurities in the photoelectric conversion layer 34, which may contain a plurality of layer regions formed of materials having different semiconductor properties such as n-type, p-type, and i-type.

For example, in a CIGS semiconductor, when provided with a distribution in the amount of Ga in the direction of thickness in the photoelectric conversion layer 34, the band gap width, carrier mobility, etc. can be controlled, and thus high photoelectric conversion efficiency is achieved.

The photoelectric conversion layers 34 may contain one or two or more kinds of semiconductors other than group I-III-VI semiconductors. Such semiconductors other than group I-III-VI semiconductors include a semiconductor formed of a group IVb element such as Si (group IV semiconductor), a semiconductor formed of a group Mb element and a group Vb element (group III-V semiconductor) such as GaAs, and a semiconductor formed of a group IIb element and a group VIb (group II-VI semiconductor) such as CdTe. The photoelectric conversion layers 34 may contain any other component than a semiconductor and impurities used to obtain a desired conductivity type, provided that no detrimental effects are thereby produced on the properties.

The photoelectric conversion layers 34 may contain a group I-III-VI semiconductor in any amount as deemed appropriate. The ratio of group I-III-VI semiconductor contained in the photoelectric conversion layers 34 is preferably 75 mass % or more and, more preferably, 95 mass % or more and, most preferably, 99 mass % or more.

Note that when the photoelectric conversion layers 34 in the embodiment are made of compound semiconductors formed of a group Ib element, a group IIIb element, and a group VIb element, the metal base 12 is preferably formed of carbon steel or ferrite stainless steel, and the back electrodes 32 are preferably made of molybdenum.

Exemplary known methods of forming the CIGS layer include 1) simultaneous multi-source co-evaporation method, 2) selenization method, 3) sputtering method, 4) hybrid sputtering method, and 5) mechanochemical processing method.

1) Known multi-source co-evaporation methods include:

the three-stage method (J. R. Tuttle et al., Mat. Res. Soc. Symp. Proc., Vol. 426 (1966), p. 143, etc.), and the co-evaporation method of the EC group (L. Stolt et al.: Proc. 13th ECPVSEC (1995, Nice) 1451, etc.).

According to the former three-phase method, firstly, In, Ga, and Se are simultaneously vapor deposited under high vacuum at a substrate temperature of 300 degree C., which is then increased to 500-560 degree C. to simultaneously vapor-deposit Cu and Se, whereupon In, Ga, and Se are further simultaneously evaporated. The latter simultaneous evaporation method by EC group is a method which involves evaporating copper-excess CIGS in the earlier stage of evaporation, and evaporating indium-excess CIGS in the latter half of the stage.

Improvements have been made on the foregoing methods to improve the crystallinity of CIGS films, and the following methods are known:

a) Method using ionized Ga (H. Miyazaki et al., Phys. Stat. Sol. (a), Vol. 203 (2006), p. 2603, etc.);
b) Method using cracked Se (a pre-printed collection of speeches given at the 68th Academic Lecture by the Japan Society of Applied Physics) (autumn, 2007, Hokkaido Institute of Technology), 7P-L-6, etc.);
c) Method using radicalized Se (a pre-printed collection of speeches given at the 54th Academic Lecture by the Japan Society of Applied Physics) (spring, 2007, Aoyama Gakuin Univ.), 29P-ZW-10, etc.); and
d) Method using a light excitation process (a pre-printed collection of speeches given at the 54th Academic Lecture by the Japan Society of Applied Physics) (spring, 2007, Aoyama Gakuin Univ.), 29P-ZW-14, etc.).

2) The selenization method is also called a two-stage method, whereby, firstly, a metal precursor formed of a laminated film such as a copper layer/indium layer, a (copper-gallium) layer/indium layer or the like is formed by sputter deposition, vapor deposition, or electrodeposition, and the film thus formed is heated in selenium vapor or hydrogen selenide to a temperature of 450-550 degree C. to produce a selenide such as Cu(In₁₋ₓGaₓ)Se₂ by thermal diffusion reaction. This method is called vapor-phase selenization. Another exemplary method is solid-phase selenization in which solid-phase selenium is deposited on a metal precursor film and selenized by a solid-phase diffusion reaction using the solid-phase selenium as the selenium source.

In order to avoid abrupt volume expansion that may take place during the selenization, selenization is implemented by known methods including a method in which selenium is previously mixed into the metal precursor film at a given ratio (T. Nakada et al., Solar Energy Materials and Solar Cells, 35 (1994), 204-214, etc.); and a method in which selenium is sandwiched between thin metal films (e.g., as in Cu layer/In layer/Se layer Cu layer/In layer/Se layer) to form a multi-layer precursor film (T. Nakada et al., Proc. of 10th European Photovoltaic Solar Energy Conference (1991), 887-890, etc.).

An exemplary method of forming a graded band gap CIGS film is a method which involves first depositing a Cu—Ga alloy film, depositing an In film thereon, and selenizing, while making a Ga concentration gradient in the film thickness direction using natural thermal diffusion (K. Kushiya et al., Tech. Digest 9th Photovoltaic Science and Engineering Conf. Miyazaki, 1996 (Intn. PVSEC-9, Tokyo, 1996), p. 149, etc.). 3) Known sputter deposition method include:

a technique using CuInSe₂ polycrystal as a target, one called two-source sputtering using H₂Se/Ar mixed gas as sputter gas with Cu₂Se and In₂Se₃ as targets (J. H. Ermer et al., Proc. 18th IEEE Photovoltaic Specialists Conf. (1985), 1655-1658, etc.) and a technique called three-source sputtering whereby a Cu target, an In target, and an Se or CuSe target are sputtered in Ar gas (T. Nakada et al., Jpn. J. Appl. Phys., 32 (1993), L1169-L1172, etc.).

4) Exemplary known methods for hybrid sputtering include the aforementioned sputtering method in which Cu and In metals are subjected to DC sputtering, while only Se is vapor-deposited (T. Nakada et al., Jpn. Appl. Phys., 34 (1995), 4715-4721, etc.).

5) An exemplary method for mechanochemical processing includes one in which a material selected according to the CIGS composition is placed in a planetary ball mill container and mixed by mechanical energy to obtain pulverized CIGS, which is then applied to a substrate by screen printing and annealed to obtain a CIGS film (T. Wada et al., Phys. Stat. Sol. (a), Vol. 203 (2006), p. 2593, etc.).

Other exemplary methods for forming CIGS films include screen printing, close-spaced sublimation, MOCVD and spraying (wet deposition). For example, crystals with a desired composition can be obtained by a method which involves forming a fine particle film containing a group Ib element, a group Mb element and a group VIb element on a substrate by, for example, screen printing (wet deposition) or spraying (wet deposition) and subjecting the fine particle film to pyrolysis treatment (which may be a pyrolysis treatment carried out under a group VIb element atmosphere) (JP 9-74065 A, JP 9-74213 A, etc.).

The alkali supply layer 50 is to provide alkali metal, for example, during formation of the photoelectric conversion layer 34 so as to diffuse the alkali metal, such as Na, for example, into the photoelectric conversion layer 34 (CIGS layer) In this embodiment, the alkali supply layer 50 is preferably made of soda lime glass. When the alkali supply layer 50 is made of soda lime glass, RF sputtering can be used, for example.

The alkali supply layer 50 may have a single-layer structure, or may have a multiple-layer structure in which layers of different compositions are laminated.

Exemplary alkali metals include Li, Na, K, Rb, and Cs. Exemplary alkali-earth metals include Be, Mg, Ca, Sr, and Ba. For reasons such as ease of achieving a chemically safe and easy-to handle compound, ease of discharge from the alkali supply layer 50 by heat, and a high crystallinity improvement effect of the photoelectric conversion layers 34, the alkali metal is preferably at least one kind selected from Na, K, Rb, and Cs, more preferably Na and/or K, and specially preferably Na.

Additionally, since a thick alkali supply layer 50 makes the layers more susceptible to delamination, the alkali supply layer 50 preferably has a thickness of 50 nm to 200 nm.

In this embodiment, since the content (density) of the alkali metal of the alkali supply layer 50 is sufficiently high, even when the film thickness of the alkali supply layer 50 is 50 nm to 200 nm, alkali metals sufficient to improve the conversion efficiency can be supplied to the photoelectric conversion layer 34.

Next, the manufacturing method of the thin-film solar cell 30 of the embodiment will be described.

First, the substrate 10 formed as described above is first prepared.

Next, a soda lime glass film, for example, is formed on the front surface 16a of one insulation layer 16 of the substrate 10 as the alkali supply layer 50 by RF sputtering using a film deposition apparatus.

Then, a molybdenum film serving as the back electrodes 32 is formed on the surface 50a of the alkali supply layer 50 by sputtering using, for example, a film deposition apparatus.

Then, for example, laser scribing is used to scribe the molybdenum film at the first predetermined position to form the separation grooves (P1) 33 extending in the width direction of the substrate 10. The back electrodes 32 separated from each other by the separation grooves (P1) 33 are thus formed.

Then, for example, a CIGS layer, which serves as a photoelectric conversion layer 34 (p-type semiconductor layer), is formed by any of the film deposition methods described above using a film deposition apparatus, so as to cover the back electrodes 32 and fill in the separation grooves (P1) 33.

Then, a CdS layer (n-type semiconductor layer) serving as the buffer layer 36 is formed on the CIGS layer by, for example, chemical bath deposition (CBD) method. A p-n junction semiconductor layer is thus formed.

Then, laser scribing is used to scribe the second position, which differs from the first position of the separation grooves (P1) 33, so as to form grooves (P2) 37 extending in the width direction of the substrate 10 and reach the back electrodes 32.

Then, a layer of ZnO doped with, for example, Al, B, Ga, Sb or the like, which serves as the transparent electrodes 38, is formed on the buffer layer 36 by sputtering or coating using a film deposition apparatus so as to fill the grooves (P2) 37.

Then, laser scribing is used to scribe a third position, which differs from the first position of the separation grooves (P1) 33 and the second position of the grooves (P2) 37, so as to form opening grooves (P3) 39 extending in the width direction of the substrate 10 and reach the back electrodes 32. Thus, a plurality of the power generating cells 54 are formed on the laminated body of the substrate 10 and the alkali supply layer 50 to form the power generating layer 56.

Then, the photoelectric conversion elements 40 formed on the rightmost and leftmost back electrodes 32 in the longitudinal direction L of the substrate 10 are removed by, for example, laser scribing or mechanical scribing, to expose the back electrodes 32. Then, the first conductive member 42 and the second conductive member 44 are connected by, for example, ultrasonic soldering onto the rightmost and leftmost back electrodes 32, respectively.

The thin-film solar cell 30 in which the plurality of photoelectric conversion elements 40 are connected in series can be thus manufactured as shown in FIG. 5.

If necessary, a bond/seal layer (not shown), a water vapor barrier layer (not shown), and a surface protection layer (not shown) are arranged on the front side of the resulting thin-film solar cell 30, and a bond/seal layer (not shown) and a back sheet (not shown) are formed on the back side of the thin-film solar cell 30, that is, on the back side of the substrate 10, and these layers are integrated by, vacuum lamination, for example. A thin-film solar cell module is thus obtained.

In the thin-film solar cell 30 of this embodiment, even if the substrate 10 is exposed to a high-temperature environment over 500 degree C. during formation of the photoelectric conversion layer 34, for example, the tensile stress incurred by the anodized film due to the difference in the thermal expansion coefficients between the anodized film and the metallic substrate 15 can be mitigated and generation of breaks and cracks can be inhibited due to the fact that in the substrate 10, the internal stress of the anodized film of the insulation layer 16 at room temperature is compressive stress, and the magnitude of strain is 0.005-0.25%. As a result, a compound semiconductor can be formed as the photoelectric conversion layer 34 at 500 degree C. or higher. The compound semiconductor constituting the photoelectric conversion layer 34 can improve the photoelectric conversion characteristics when formed at higher temperatures, and thus, it is possible to manufacture the photoelectric conversion element 40 having the photoelectric conversion layers 34 with improved photoelectric conversion characteristics.

Further, in the thin-film solar cell 30 of this embodiment, even if breaks or cracks occur in the insulation layer 16 of the substrate 10 during use, opening of those breaks or cracks is inhibited and insulation properties (breakdown voltage characteristics) are maintained because compressive strain has been generated in the insulation layer 16. Thus, a thin-film solar cell 30 with long-term reliability and excellent durability and storage life can be obtained. Moreover, the thin-film solar cell module also has excellent durability and storage life.

Furthermore, addition of the alkali supply layer 50 allows controlling the precision and reproducibility of the amount of alkali metal supplied to the photoelectric conversion layer 34 (CIGS layer). The conversion efficiency of the photoelectric conversion elements 40 can be thus improved and the photoelectric conversion elements 40 can be thus manufactured at a high yield.

Also, in this embodiment, the substrate 10 is produced by the roll-to-roll process, and is flexible. This makes it possible to manufacture the photoelectric conversion element 40 and the thin-film solar cell 30 as well using the roll-to-roll process, while transporting the substrate 10 in the longitudinal direction L. With the thin-film solar cell 30 thus manufactured using the inexpensive roll-to-roll process, the cost of manufacturing the thin-film solar cell 30 can be reduced. As a result, the cost of a thin-film solar cell module can be reduced.

The temperature is increased to 500 degree C. or more during formation of the photoelectric conversion layer 34 (CIGS layer), but it is acceptable if the substrate undergoes the annealed treatment before this temperature increase and has an insulation layer 16 having compressive strain. For this reason, using a substrate in which an anodized film was formed without having undergone the above-described annealing treatment, for example, it is acceptable to perform annealing at a heating temperature of 100-600 degree C. with a holding time of 1 second to 100 hours while transporting the substrate by a roll to roll process, for example, to thereby create an insulation layer 16 having a strain value equivalent to compression at room temperature, and then successively form the back electrodes 32 and photoelectric conversion elements 40 such as the photoelectric conversion layer 34 (CIGS layer) as described above without reducing the substrate temperature to room temperature. Here, the strain value equivalent to compression at room temperature indicates the strain value of only compressive strain when the substrate is returned to room temperature immediately after annealing treatment. It does not make a difference if the subsequent formation temperatures of the back electrodes 32 and photoelectric conversion layer 34 (CIGS layer), etc., are the same as the annealing temperature. In particular, in many cases the formation temperature of the photoelectric conversion layer 34 (CIGS layer) is higher than the annealing temperature, as it is often 500 degree C. or more. In this case, there is no reheating step due to the fact that the temperature is increased continuously after the annealing treatment, which is preferred in terms of cost reduction. Even if the formation temperatures of the back electrodes 32 and photoelectric conversion layer 34 (CIGS layer), etc., are lower than the annealing temperature, there is no reheating step due to the fact that the temperature is increased continuously, which is preferred in terms of cost reduction.

In the thin-film solar cell 30 in this embodiment, the diffusion prevention layer may be provided between the alkali supply layer 50 and the insulation layer 16 in order to prevent the alkali metal contained in the alkali supply layer 50 from diffusing to the substrate 10 and to increase the amount of the alkali metal diffused to the photoelectric conversion layer 34. In this case, since the amount of the alkali metal diffused to the photoelectric conversion layer 34 can be increased, the photoelectric conversion element 40 with higher conversion efficiency can be obtained.

Further, the provision of the diffusion prevention layer makes it possible to achieve favorable conversion efficiency of the photoelectric conversion element even if the alkali supply layer is thin. In this embodiment, since the alkali supply layer 50 can be made thin, it is possible to shorten the fabrication time of the alkali supply layer 50 and improve the productivity of the photoelectric conversion element 40 and thus the thin-film solar cell 30. This also makes it possible to keep the alkali supply layer 50 from becoming the origin of delamination.

The diffusion prevention layer can be made of nitrides, for example, and is preferably an insulator.

Specifically, as a diffusion prevention layer of nitride, TiN (9.4 ppm/K), ZrN (7.2 ppm/K), BN (6.4 ppm/K), and AlN (5.7 ppm/K) can be used. Of these, the diffusion prevention layer is preferably a material having a small difference in thermal expansion coefficient from that of the insulation layer 16 and aluminum anodized film of the substrate 10, and is thus more preferably made of ZrN, BN, or AlN. Of these, the insulators are BN and AlN, and these are more preferable as diffusion prevention layers.

The diffusion prevention layer may be made of oxide. In this case, TiO₂ (9.0 ppm/K), ZrO₂ (7.6 ppm/K), HfO₂ (6.5 ppm/K), and Al₂O₃ (8.4 ppm/K) can be used as oxide. The diffusion prevention layer is preferably an insulator even when it is made of oxide.

Presumably, while the oxide film prevents diffusion of Na to the substrate 10 due to Na within the film, the nitride film does not readily contain alkali metal such as Na within the film and thus inhibits diffusion to the inside of the nitride film, thereby promoting Na diffusion to the CIGS layer more than the alkali supply layer. Therefore, as a diffusion prevention layer, the diffusion prevention layer of nitride is more effective than the diffusion prevention layer of oxide in diffusing the alkali metal into the photoelectric conversion layer 34 (CIGS layer). Therefore, the diffusion prevention layer of nitride is more preferable.

The diffusion prevention layer is preferably thick since increased thickness enhances its function of preventing diffusion into the substrate 10 and its function of increasing the amount of alkali metal diffused into the photoelectric conversion layers 34. Nevertheless, since a greater thickness causes the diffusion prevention layer to become the origin of delamination, the diffusion prevention layer preferably has a thickness of 10 nm to 200 nm, and more preferably 10 nm to 100 nm.

In this embodiment, the diffusion prevention layer is made of an insulator, making it possible to further improve the insulation properties (withstand voltage characteristics) of the substrate 10. Further, as described above, the substrate 10 exhibits excellent heat resistance. The thin-film solar cell 30 can thus exhibit even better durability and storage life. For this reason, the thin-film solar cell module also has better durability and storage life.

In this embodiment, the substrate 10 is used for the substrate of the thin-film solar cell, but the present invention is not limited thereto. The substrate can be used for a thermoelectric module that generates electricity using the difference of temperature using, for example, a thermoelectric element. When it is used for a thermoelectric module, a thermoelectric element can be integrated and connected in series.

Further, in addition to the thermoelectric module, for example, various semiconductor elements can be formed on the substrate 10 to provide a semiconductor device. In this semiconductor device as well, the roll-to-roll process can be used for formation of semiconductor elements. Therefore, the roll-to-roll process for formation of semiconductor elements is preferably used for higher productivity.

Furthermore, on the substrate 10, light-emitting elements that use organic ELs, LDs and LEDs may be formed to make light-emitting devices. Note that as light-emitting elements, those called the top emission type, for example, may be used.

Further, on the substrate 10, electronic elements such as resistors, transistors, diode, coils and the like may be formed to make electronic circuits.

In such light-emitting elements and electronic circuits, use of a roll to roll process is preferred as long as formation of the light-emitting elements and electronic elements is possible, because it improves productivity.

Further, the semiconductor devices, electronic circuits and light-emitting devices have excellent durability and storage life because the used metal substrate with an insulation layer has excellent cracking resistance and excellent electrical insulation properties.

In the manufacture of thermoelectric modules, semiconductor devices, electronic circuits and light-emitting elements as well, a substrate that has been provided with compressive strain does not necessarily have to be used as long as the anodized film can be provided with strain equivalent to compression at room temperature by performing the annealing treatment described above prior to processes in which the temperature is increased to a level that adversely affects the anodized film due to the difference in the thermal expansion coefficients between the anodized film and the metal substrate, for example, 500 degree C. or above. Here, the strain value equivalent to compression at room temperature indicates the strain value of only compressive strain when the substrate is returned to room temperature immediately after annealing treatment.

In this case, after the temperature is increased in the annealing treatment, it can be subjected to the various manufacturing steps of the thermionic modules, semiconductor devices, electronic circuits and light-emitting elements without reducing the substrate temperature to room temperature. It does not make a difference if the various subsequent manufacturing process temperatures of the thermionic modules, semiconductor devices, electronic circuits and light-emitting elements are the same as the annealing temperature. In particular, in many cases the formation temperature of the semiconductor elements is higher than the annealing temperature, as it is often 500 degree C. or more. In this case, there is no reheating step due to the fact that the temperature is increased continuously after the annealing treatment, which is preferred in terms of cost reduction. Even if the process temperature is lower than the annealing temperature, there is no reheating step due to the fact that the temperature is increased continuously, which is preferred in terms of cost reduction.

The present invention is basically as described above. The metal substrate with an insulation film used in semiconductor devices and solar cells and the like and the manufacturing method thereof, the semiconductor device and manufacturing method thereof, the solar cell and manufacturing method thereof, the electronic circuit and manufacturing method thereof and the light-emitting element and manufacturing method thereof of the present invention have been described above in detail, but the present invention is not limited to the above embodiments, and various improvements or design modifications may be made without departing from the scope and spirit of the present invention.

### Example 1

Example 1 of the metal substrate with an insulation layer of the present invention will be specifically described below.

In this Example 1, working example numbers 1 through 68 and comparison example numbers 1 through 22 shown below were manufactured, and the magnitude of strain and Young's modulus of the anodized film which forms the insulation layer were measured for each, and internal stress was calculated. Further, a thermal strain test and an insulation breakdown test were performed, and thermal strain resistance and insulation breakdown voltage were assessed.

Note that in working example numbers 33 through 68, metal substrates with an insulation layer were each produced using a composite substrate of aluminum and another metal, and the anodized film that forms the insulation layer was assessed.

The results of thermal strain resistance and insulation breakdown voltage of working example numbers 1 through 68 and comparison example numbers 1 through 22 are shown in Table 4 through Table 6 below.

In Table 1 through Table 3 below, [1] through [8] shown in the Metallic Substrate column indicate the structure of the metallic substrate. [1] is a single material of industrial aluminum of purity 99.5%. [2] is a single material of high-purity aluminum of purity 99.99%. [3] is a clad material of industrial aluminum of purity 99.5% and SUS430. [4] is a clad material of high-purity aluminum of purity 99.99% and SUS430. [5] is a clad material of high-purity aluminum of purity 99.99% and SPCC low-carbon steel (JIS standard). [6] is a clad material of high-purity aluminum of purity 99.5% and SPCC low-carbon steel (JIS standard). [7] is a laminated material of aluminum formed by vapor deposition and SUS430. [8] is a laminated material of aluminum layer formed by vapor deposition and 42 invar material (42% Ni steel).

[1] and [2] are each a single material of aluminum 300 micrometers thick.

[3] through [8] are metal substrates in which an aluminum base is formed on both surfaces of a metal base 100 micrometers thick.

As described above, the magnitude of strain was determined by measuring the length of the anodized film of the metal substrate with an insulation layer, then measuring the length of the anodized film after the metal substrate had been removed by dissolving it, and then determining the magnitude of the strain based on the lengths of the anodized film before and after removal of the metal substrate.

The Young's modulus was measured using a PICODENTORT™ HM500H made by Fischer Instruments.

The internal stress was determined using the magnitude of strain and the Young's modulus.

In the thermal strain test, rapid heating was performed on the metal substrate with an insulation layer at 500 K/minute from room temperature to the test temperature, and after holding for 15 minutes, the temperature was decreased to room temperature, and the presence of cracks in the anodized film was examined.

For crack generation, a visual examination was performed on the intact metal substrate with an insulation layer, and it was also performed using an optical microscope on the insulation layer after the metal substrate was removed by dissolving and the insulation was taken off.

If there was no cracking seen by either visual or optical microscope observation, the example was marked with an O. If there was no cracking seen by visual observation but there was cracking seen by optical microscope observation, the example was marked with a triangle. If cracking was seen by both visual and optical microscope observation, it was marked with an X.

In the insulation breakdown voltage test, the metal substrate with an insulation layer was cut into test specimens 5 cm×5 cm in size, and a top gold electrode of diameter 3 cm was formed on each test specimen.

After a top gold electrode was formed on each test specimen, voltage was applied between the top electrode and the aluminum substrate, and the applied voltage was gradually increased at 10-volt intervals. The voltage at which insulation breakdown occurred was taken as the insulation breakdown voltage.

Note that substrates in which insulation breakdown did not occur even when the applied voltage was 1000 V are marked as “1000 V or above” in the Insulation Breakdown Voltage column. Also, substrates in which insulation breakdown occurred when the applied voltage was 10 V are marked as “not measurable” in the Insulation Breakdown Voltage column.

TABLE 1

| | | Anodization Conditions | | | | | | | | |
|---|---|---|---|---|---|---|---|---|---|---|
| Working | | | Solution | | Film | | | Young's | | |
| Example | Metallic | Electrolytic | Temperature | Voltage | Thickness | Strain at Room | | Modulus | Internal Stress | |
| No. | Substrate | Solution | (degree C.) | (V) | (micrometer) | Temperature | | (GPa) | (MPa) | |
| 1 | [1] | 0.5M oxalic acid | 55 | 40 | 10 | 0.024% | Compressive | 70 | 17 | Compressive |
| 2 | [1] | 0.5M oxalic acid | 55 | 40 | 5 | 0.018% | Compressive | 71 | 13 | Compressive |
| 3 | [1] | 0.5M oxalic acid | 55 | 20 | 5 | 0.020% | Compressive | 65 | 13 | Compressive |
| 4 | [1] | 0.5M oxalic acid | 75 | 40 | 5 | 0.031% | Compressive | Not | — | Compressive |
| | | | | | | | | measureable | | |
| 5 | [1] | 0.5M oxalic acid | 75 | 30 | 5 | 0.029% | Compressive | Not | — | Compressive |
| | | | | | | | | measureable | | |
| 6 | [2] | 0.5M oxalic acid | 55 | 40 | 20 | 0.012% | Compressive | 72 | 9 | Compressive |
| 7 | [2] | 0.5M oxalic acid | 55 | 40 | 10 | 0.015% | Compressive | 70 | 11 | Compressive |
| 8 | [2] | 0.5M oxalic acid | 55 | 40 | 5 | 0.009% | Compressive | 68 | 6 | Compressive |
| 9 | [2] | 0.5M oxalic acid | 75 | 40 | 7 | 0.019% | Compressive | Not | — | Compressive |
| | | | | | | | | measureable | | |
| 10 | [2] | 0.5M oxalic acid | 75 | 40 | 3 | 0.021% | Compressive | Not | — | Compressive |
| | | | | | | | | measureable | | |
| 11 | [2] | 0.5M oxalic acid | 75 | 30 | 5 | 0.025% | Compressive | Not | — | Compressive |
| | | | | | | | | measureable | | |
| 12 | [2] | 1M sulfuric acid | 50 | 15 | 7 | 0.035% | Compressive | Not | — | Compressive |
| | | | | | | | | measureable | | |
| 13 | [2] | 1M sulfuric acid | 50 | 15 | 4 | 0.031% | Compressive | Not | — | Compressive |
| | | | | | | | | measureable | | |
| 14 | [2] | 1M sulfuric acid | 60 | 15 | 3 | 0.046% | Compressive | Not | — | Compressive |
| | | | | | | | | measureable | | |
| 15 | [2] | 1M malonic acid | 60 | 80 | 10 | 0.048% | Compressive | 92 | 44 | Compressive |
| 16 | [2] | 1M malonic acid | 60 | 110 | 10 | 0.043% | Compressive | 90 | 39 | Compressive |
| 17 | [2] | 1M malonic acid | 80 | 80 | 10 | 0.086% | Compressive | 82 | 71 | Compressive |
| 18 | [2] | 1M malonic acid | 80 | 80 | 20 | 0.074% | Compressive | 84 | 62 | Compressive |
| 19 | [2] | 1M malonic acid | 80 | 100 | 10 | 0.079% | Compressive | 83 | 66 | Compressive |
| 20 | [2] | 1M tartaric acid | 80 | 160 | 10 | 0.097% | Compressive | 85 | 82 | Compressive |
| 21 | [2] | 3M tartaric acid | 80 | 160 | 10 | 0.085% | Compressive | 82 | 70 | Compressive |
| 22 | [2] | 1M citric acid | 80 | 250 | 10 | 0.052% | Compressive | 86 | 45 | Compressive |
| 23 | [2] | 1M malic acid | 80 | 220 | 5 | 0.061% | Compressive | 90 | 55 | Compressive |
| 24 | [2] | 0.5M oxalic acid | 55 | 40 | 3 | 0.017% | Compressive | 69 | 12 | Compressive |
| 25 | [2] | 0.5M oxalic acid | 55 | 40 | 5 | 0.019% | Compressive | 70 | 13 | Compressive |
| 26 | [2] | 0.5M oxalic acid | 55 | 40 | 10 | 0.016% | Compressive | 64 | 10 | Compressive |
| 27 | [2] | 1M malonic acid | 50 | 100 | 10 | 0.032% | Compressive | 90 | 29 | Compressive |
| 28 | [2] | 1M malonic acid | 50 | 130 | 10 | 0.029% | Compressive | 90 | 26 | Compressive |
| 29 | [2] | 1M malonic acid | 80 | 80 | 3 | 0.079% | Compressive | 84 | 66 | Compressive |
| 30 | [2] | 1M malonic acid | 80 | 80 | 5 | 0.082% | Compressive | 83 | 68 | Compressive |
| 31 | [2] | 1M malonic acid | 60 | 80 | 25 | 0.028% | Compressive | 76 | 21 | Compressive |
| 32 | [2] | 1M malonic acid | 50 | 130 | 25 | 0.031% | Compressive | 89 | 28 | Compressive |
| 33 | [3] | 0.5M oxalic acid | 55 | 40 | 20 | 0.012% | Compressive | 72 | 9 | Compressive |
| 34 | [3] | 0.5M oxalic acid | 55 | 40 | 10 | 0.009% | Compressive | 68 | 6 | Compressive |

TABLE 2

| | | Anodization Conditions | | | | | | | | |
|---|---|---|---|---|---|---|---|---|---|---|
| Working | | | Solution | | Film | | | Young's | | |
| Example | Metallic | Electrolytic | Temperature | Voltage | Thickness | Strain at Room | | Modulus | Internal Stress | |
| No. | Substrate | Solution | (degree C.) | (V) | (micrometer) | Temperature | | (GPa) | (MPa) | |
| 35 | [3] | 0.5M oxalic acid | 55 | 40 | 5 | 0.015% | Compressive | 69 | 10 | Compressive |
| 36 | [3] | 0.5M oxalic acid | 75 | 40 | 7 | 0.028% | Compressive | Not | — | Compressive |
| | | | | | | | | measureable | | |
| 37 | [3] | 0.5M oxalic acid | 75 | 40 | 3 | 0.030% | Compressive | Not | — | Compressive |
| | | | | | | | | measureable | | |
| 38 | [3] | 0.5M oxalic acid | 75 | 30 | 5 | 0.021% | Compressive | Not | — | Compressive |
| | | | | | | | | measureable | | |
| 39 | [3] | 1M sulfuric acid | 50 | 15 | 7 | 0.016% | Compressive | Not | — | Compressive |
| | | | | | | | | measureable | | |
| 40 | [3] | 1M sulfuric acid | 50 | 15 | 4 | 0.011% | Compressive | Not | — | Compressive |
| | | | | | | | | measureable | | |
| 41 | [3] | 1M sulfuric acid | 60 | 15 | 3 | 0.015% | Compressive | Not | — | Compressive |
| | | | | | | | | measureable | | |
| 42 | [3] | 1M malonic acid | 60 | 80 | 10 | 0.017% | Compressive | 89 | 15 | Compressive |
| 43 | [3] | 1M malonic acid | 60 | 110 | 10 | 0.021% | Compressive | 91 | 19 | Compressive |
| 44 | [3] | 1M malonic acid | 80 | 80 | 10 | 0.030% | Compressive | 82 | 25 | Compressive |
| 45 | [3] | 1M malonic acid | 80 | 80 | 20 | 0.026% | Compressive | 76 | 20 | Compressive |
| 46 | [3] | 1M malonic acid | 80 | 100 | 10 | 0.028% | Compressive | 81 | 23 | Compressive |
| 47 | [3] | 1M malonic acid | 80 | 80 | 20 | 0.034% | Compressive | 77 | 26 | Compressive |
| 48 | [3] | 1M tartaric acid | 80 | 160 | 10 | 0.042% | Compressive | 82 | 34 | Compressive |
| 49 | [3] | 3M tartaric acid | 80 | 160 | 10 | 0.032% | Compressive | 83 | 27 | Compressive |
| 50 | [3] | 1M citric acid | 80 | 250 | 10 | 0.033% | Compressive | 86 | 28 | Compressive |
| 51 | [3] | 1M malic acid | 80 | 220 | 5 | 0.041% | Compressive | 87 | 36 | Compressive |
| 52 | [4] | 0.5M oxalic acid | 75 | 30 | 5 | 0.028% | Compressive | Not | — | Compressive |
| | | | | | | | | measureable | | |
| 53 | [4] | 1M sulfuric acid | 60 | 15 | 7 | 0.013% | Compressive | Not | — | Compressive |
| | | | | | | | | measureable | | |
| 54 | [4] | 1M malonic acid | 80 | 80 | 10 | 0.029% | Compressive | 75 | 22 | Compressive |
| 55 | [4] | 1M tartaric acid | 80 | 160 | 10 | 0.039% | Compressive | 79 | 31 | Compressive |
| 56 | [5] | 0.5M oxalic acid | 75 | 30 | 7 | 0.038% | Compressive | Not | — | Compressive |
| | | | | | | | | measureable | | |
| 57 | [6] | 0.5M oxalic acid | 75 | 30 | 7 | 0.041% | Compressive | Not | — | Compressive |
| | | | | | | | | measureable | | |
| 58 | [7] | 0.5M oxalic acid | 75 | 30 | 7 | 0.032% | Compressive | Not | — | Compressive |
| | | | | | | | | measureable | | |
| 59 | [8] | 0.5M oxalic acid | 75 | 30 | 7 | 0.029% | Compressive | Not | — | Compressive |
| | | | | | | | | measureable | | |
| 60 | [4] | 0.5M oxalic acid | 55 | 40 | 8 | 0.015% | Compressive | 72 | 11 | Compressive |
| 61 | [4] | 0.5M oxalic acid | 55 | 40 | 6 | 0.012% | Compressive | 73 | 9 | Compressive |
| 62 | [4] | 0.5M oxalic acid | 55 | 40 | 10 | 0.016% | Compressive | 68 | 11 | Compressive |
| 63 | [4] | 1M malonic acid | 50 | 100 | 10 | 0.022% | Compressive | 85 | 19 | Compressive |
| 64 | [4] | 1M malonic acid | 50 | 130 | 10 | 0.016% | Compressive | 90 | 14 | Compressive |
| 65 | [4] | 1M malonic acid | 80 | 80 | 3 | 0.039% | Compressive | 72 | 28 | Compressive |
| 66 | [4] | 1M malonic acid | 80 | 80 | 5 | 0.034% | Compressive | 76 | 26 | Compressive |
| 67 | [4] | 1M malonic acid | 60 | 80 | 25 | 0.020% | Compressive | 93 | 19 | Compressive |
| 68 | [4] | 1M malonic acid | 50 | 130 | 25 | 0.014% | Compressive | 88 | 12 | Compressive |

TABLE 3

| | | Anodization Conditions | | | | | | | | |
|---|---|---|---|---|---|---|---|---|---|---|
| Comparison | | | Solution | | Film | | | Young's | | |
| Example | Metallic | Electrolytic | Temperature | Voltage | Thickness | Strain at Room | | Modulus | Internal Stress | |
| No. | Substrate | Solution | (degree C.) | (V) | (micrometer) | Temperature | | (GPa) | (MPa) | |
| 1 | [1] | 0.5M oxalic acid | 5 | 60 | 10 | 0.021% | Tensile | 123 | 26 | Tensile |
| 2 | [1] | 0.5M oxalic acid | 16 | 40 | 10 | 0.008% | Tensile | 112 | 9 | Tensile |
| 3 | [1] | 0.5M oxalic acid | 16 | 40 | 20 | 0.042% | Tensile | 95 | 10 | Tensile |
| 4 | [1] | 0.5M oxalic acid | 16 | 40 | 30 | 0.055% | Tensile | 103 | 57 | Tensile |
| 5 | [1] | 0.5M oxalic acid | 16 | 40 | 40 | 0.058% | Tensile | 106 | 61 | Tensile |
| 6 | [1] | 0.5M oxalic acid | 16 | 50 | 10 | 0.024% | Tensile | 110 | 26 | Tensile |
| 7 | [1] | 0.5M oxalic acid | 16 | 80 | 10 | 0.016% | Tensile | 98 | 16 | Tensile |
| 8 | [1] | 0.5M oxalic acid | 16 | 100 | 10 | 0.005% | Tensile | 103 | 5 | Tensile |
| 9 | [1] | 0.5M oxalic acid | 35 | 40 | 10 | 0.046% | Tensile | 77 | 35 | Tensile |
| 10 | [1] | 1M sulfuric acid | 16 | 15 | 10 | 0.002% | Tensile | 76 | 2 | Tensile |
| 11 | [1] | 1M sulfuric acid | 35 | 15 | 10 | 0.010% | Tensile | 60 | 6 | Tensile |
| 12 | [1] | 1M phosphoric | 5 | 100 | 10 | 0.034% | Tensile | 125 | 43 | Tensile |
| | | acid | | | | | | | | |
| 13 | [1] | 1M malonic acid | 5 | 80 | 10 | 0.007% | Tensile | 82 | 6 | Tensile |
| 14 | [1] | 1M malonic acid | 5 | 110 | 10 | 0.011% | Tensile | 89 | 10 | Tensile |
| 15 | [2] | 0.5M oxalic acid | 16 | 40 | 3 | Not | — | Not | — | — |
| | | | | | | measurable | | measured | | |
| 16 | [2] | 0.5M oxalic acid | 16 | 40 | 5 | 0.009% | Tensile | 105 | 9 | Tensile |
| 17 | [2] | 0.5M oxalic acid | 16 | 40 | 10 | 0.006% | Tensile | 108 | 6 | Tensile |
| 18 | [2] | 1M sulfuric acid | 35 | 15 | 10 | 0.008% | Tensile | 54 | 4 | Tensile |
| 19 | [2] | 0.5M oxalic acid | 16 | 40 | 1 | Not | — | Not | — | — |
| | | | | | | measurable | | measured | | |
| 20 | [2] | 0.5M oxalic acid | 55 | 40 | 1 | Not | — | Not | — | — |
| | | | | | | measurable | | measured | | |
| 21 | [2] | 1M malonic acid | 50 | 130 | 1 | Not | — | Not | — | — |
| | | | | | | measurable | | measured | | |
| 22 | [2] | 1M malonic acid | 80 | 80 | 1 | Not | — | Not | — | — |
| | | | | | | measurable | | measured | | |

TABLE 4

| Working | Thermal Strain Test | | | | | | | | | Insulation |
|---|---|---|---|---|---|---|---|---|---|---|
| Example | Heating Temperature (degree C.) | | | | | | | | | Breakdown |
| No. | 120 | 150 | 180 | 210 | 230 | 450 | 500 | 550 | 575 | Voltage (V) |
| 1 | ∘ | ∘ | Δ | x | x | x | x | x | x | Not |
| | | | | | | | | | | measured |
| 2 | ∘ | ∘ | Δ | x | x | x | x | x | x | Not |
| | | | | | | | | | | measured |
| 3 | ∘ | ∘ | Δ | x | x | x | x | x | x | Not |
| | | | | | | | | | | measured |
| 4 | ∘ | ∘ | Δ | x | x | x | x | x | x | Not |
| | | | | | | | | | | measured |
| 5 | ∘ | ∘ | Δ | x | x | x | x | x | x | Not |
| | | | | | | | | | | measured |
| 6 | ∘ | ∘ | Δ | x | x | x | x | x | x | 1000 V |
| | | | | | | | | | | or more |
| 7 | ∘ | ∘ | x | x | x | x | x | x | x | 910 |
| 8 | ∘ | ∘ | ∘ | x | x | x | x | x | x | 510 |
| 9 | ∘ | ∘ | Δ | x | x | x | x | x | x | 630 |
| 10 | ∘ | ∘ | ∘ | x | x | x | x | x | x | 250 |
| 11 | ∘ | ∘ | Δ | x | x | x | x | x | x | 380 |
| 12 | ∘ | ∘ | x | x | x | x | x | x | x | 680 |
| 13 | ∘ | ∘ | x | x | x | x | x | x | x | 310 |
| 14 | ∘ | ∘ | Δ | x | x | x | x | x | x | 260 |
| 15 | ∘ | ∘ | Δ | x | x | x | x | x | x | 940 |
| 16 | ∘ | ∘ | Δ | x | x | x | x | x | x | 930 |
| 17 | ∘ | ∘ | ∘ | x | x | x | x | x | x | 1000 V |
| | | | | | | | | | | or more |
| 18 | ∘ | ∘ | ∘ | Δ | x | x | x | x | x | 1000 V |
| | | | | | | | | | | or more |
| 19 | ∘ | ∘ | ∘ | Δ | x | x | x | x | x | 960 |
| 20 | ∘ | ∘ | ∘ | x | x | x | x | x | x | 890 |
| 21 | ∘ | ∘ | ∘ | x | x | x | x | x | x | 790 |
| 22 | ∘ | ∘ | x | x | x | x | x | x | x | 830 |
| 23 | ∘ | ∘ | Δ | x | x | x | x | x | x | 420 |
| 24 | ∘ | ∘ | Δ | x | x | x | x | x | x | 210 |
| 25 | ∘ | ∘ | Δ | x | x | x | x | x | x | 450 |
| 26 | ∘ | ∘ | x | x | x | x | x | x | x | 860 |
| 27 | ∘ | ∘ | Δ | x | x | x | x | x | x | 910 |
| 28 | ∘ | ∘ | Δ | x | x | x | x | x | x | 880 |
| 29 | ∘ | ∘ | ∘ | x | x | x | x | x | x | 320 |
| 30 | ∘ | ∘ | Δ | x | x | x | x | x | x | 450 |
| 31 | ∘ | Δ | x | x | x | x | x | x | x | 1000 V |
| | | | | | | | | | | or more |
| 32 | ∘ | Δ | x | x | x | x | x | x | x | 1000 V |
| | | | | | | | | | | or more |
| 33 | ∘ | ∘ | ∘ | ∘ | ∘ | ∘ | ∘ | Δ | x | Not |
| | | | | | | | | | | measured |
| 34 | ∘ | ∘ | ∘ | ∘ | ∘ | ∘ | Δ | x | x | Not |
| | | | | | | | | | | measured |

TABLE 5

| Working | Thermal Strain Test | | | | | | | | | Insulation |
|---|---|---|---|---|---|---|---|---|---|---|
| Example | Heating Temperature (degree C.) | | | | | | | | | Breakdown |
| No. | 120 | 150 | 180 | 210 | 230 | 450 | 500 | 550 | 575 | Voltage (V) |
| 35 | ∘ | ∘ | ∘ | ∘ | ∘ | ∘ | ∘ | Δ | x | Not |
| | | | | | | | | | | measured |
| 36 | ∘ | ∘ | ∘ | ∘ | ∘ | ∘ | ∘ | Δ | x | Not |
| | | | | | | | | | | measured |
| 37 | ∘ | ∘ | ∘ | ∘ | ∘ | ∘ | ∘ | Δ | x | Not |
| | | | | | | | | | | measured |
| 38 | ∘ | ∘ | ∘ | ∘ | ∘ | ∘ | ∘ | Δ | x | Not |
| | | | | | | | | | | measured |
| 39 | ∘ | ∘ | ∘ | ∘ | ∘ | ∘ | ∘ | x | x | Not |
| | | | | | | | | | | measured |
| 40 | ∘ | ∘ | ∘ | ∘ | ∘ | ∘ | ∘ | x | x | Not |
| | | | | | | | | | | measured |
| 41 | ∘ | ∘ | ∘ | ∘ | ∘ | ∘ | ∘ | Δ | x | Not |
| | | | | | | | | | | measured |
| 42 | ∘ | ∘ | ∘ | ∘ | ∘ | ∘ | ∘ | Δ | x | Not |
| | | | | | | | | | | measured |
| 43 | ∘ | ∘ | ∘ | ∘ | ∘ | ∘ | ∘ | Δ | x | Not |
| | | | | | | | | | | measured |
| 44 | ∘ | ∘ | ∘ | ∘ | ∘ | ∘ | ∘ | ∘ | x | Not |
| | | | | | | | | | | measured |
| 45 | ∘ | ∘ | ∘ | ∘ | ∘ | ∘ | ∘ | ∘ | Δ | Not |
| | | | | | | | | | | measured |
| 46 | ∘ | ∘ | ∘ | ∘ | ∘ | ∘ | ∘ | ∘ | Δ | Not |
| | | | | | | | | | | measured |
| 47 | ∘ | ∘ | ∘ | ∘ | ∘ | ∘ | ∘ | Δ | x | Not |
| | | | | | | | | | | measured |
| 48 | ∘ | ∘ | ∘ | ∘ | ∘ | ∘ | ∘ | ∘ | x | Not |
| | | | | | | | | | | measured |
| 49 | ∘ | ∘ | ∘ | ∘ | ∘ | ∘ | ∘ | ∘ | x | Not |
| | | | | | | | | | | measured |
| 50 | ∘ | ∘ | ∘ | ∘ | ∘ | ∘ | ∘ | x | x | Not |
| | | | | | | | | | | measured |
| 51 | ∘ | ∘ | ∘ | ∘ | ∘ | ∘ | ∘ | Δ | x | Not |
| | | | | | | | | | | measured |
| 52 | ∘ | ∘ | ∘ | ∘ | ∘ | ∘ | ∘ | x | x | 420 |
| 53 | ∘ | ∘ | ∘ | ∘ | ∘ | ∘ | ∘ | x | x | 390 |
| 54 | ∘ | ∘ | ∘ | ∘ | ∘ | ∘ | ∘ | ∘ | Δ | 980 |
| 55 | ∘ | ∘ | ∘ | ∘ | ∘ | ∘ | Δ | Δ | x | 930 |
| 56 | ∘ | ∘ | ∘ | ∘ | ∘ | x | x | x | x | 520 |
| 57 | ∘ | ∘ | ∘ | ∘ | ∘ | ∘ | Δ | x | x | 600 |
| 58 | ∘ | ∘ | ∘ | ∘ | ∘ | ∘ | ∘ | x | x | 530 |
| 59 | ∘ | ∘ | ∘ | ∘ | ∘ | ∘ | ∘ | x | x | 530 |
| 60 | ∘ | ∘ | ∘ | ∘ | ∘ | ∘ | ∘ | Δ | x | 240 |
| 61 | ∘ | ∘ | ∘ | ∘ | ∘ | ∘ | ∘ | Δ | x | 420 |
| 62 | ∘ | ∘ | ∘ | ∘ | ∘ | ∘ | ∘ | ∘ | x | 890 |
| 63 | ∘ | ∘ | ∘ | ∘ | ∘ | ∘ | ∘ | Δ | x | 900 |
| 64 | ∘ | ∘ | ∘ | ∘ | ∘ | ∘ | ∘ | Δ | x | 840 |
| 65 | ∘ | ∘ | ∘ | ∘ | ∘ | ∘ | ∘ | ∘ | x | 370 |
| 66 | ∘ | ∘ | ∘ | ∘ | ∘ | ∘ | ∘ | Δ | x | 420 |
| 67 | ∘ | ∘ | ∘ | ∘ | ∘ | ∘ | Δ | x | x | 1000 V |
| | | | | | | | | | | or more |
| 68 | ∘ | ∘ | ∘ | ∘ | ∘ | ∘ | x | x | x | 1000 V |
| | | | | | | | | | | or more |

TABLE 6

| Comparison | Thermal Strain Test | | | | | | | | | Insulation |
|---|---|---|---|---|---|---|---|---|---|---|
| Example | Heating Temperature (degree C.) | | | | | | | | | Breakdown |
| No. | 120 | 150 | 180 | 210 | 230 | 450 | 500 | 550 | 575 | Voltage (V) |
| 1 | x | x | x | x | x | x | x | x | x | Not |
| | | | | | | | | | | measured |
| 2 | ∘ | Δ | x | x | x | x | x | x | x | Not |
| | | | | | | | | | | measured |
| 3 | ∘ | Δ | x | x | x | x | x | x | x | Not |
| | | | | | | | | | | measured |
| 4 | ∘ | Δ | x | x | x | x | x | x | x | Not |
| | | | | | | | | | | measured |
| 5 | ∘ | Δ | x | x | x | x | x | x | x | Not |
| | | | | | | | | | | measured |
| 6 | ∘ | Δ | x | x | x | x | x | x | x | Not |
| | | | | | | | | | | measured |
| 7 | ∘ | Δ | x | x | x | x | x | x | x | Not |
| | | | | | | | | | | measured |
| 8 | ∘ | Δ | x | x | x | x | x | x | x | Not |
| | | | | | | | | | | measured |
| 9 | ∘ | ∘ | x | x | x | x | x | x | x | Not |
| | | | | | | | | | | measured |
| 10 | ∘ | Δ | x | x | x | x | x | x | x | Not |
| | | | | | | | | | | measured |
| 11 | ∘ | ∘ | x | x | x | x | x | x | x | Not |
| | | | | | | | | | | measured |
| 12 | x | x | x | x | x | x | x | x | x | Not |
| | | | | | | | | | | measured |
| 13 | ∘ | x | x | x | x | x | x | x | x | Not |
| | | | | | | | | | | measured |
| 14 | ∘ | Δ | x | x | x | x | x | x | x | Not |
| | | | | | | | | | | measured |
| 15 | ∘ | x | x | x | x | x | x | x | x | 250 |
| 16 | ∘ | x | x | x | x | x | x | x | x | 380 |
| 17 | ∘ | x | x | x | x | x | x | x | x | 990 |
| 18 | ∘ | ∘ | x | x | x | x | x | x | x | 890 |
| 19 | ∘ | Δ | x | x | x | x | x | x | x | 110 |
| 20 | ∘ | ∘ | Δ | x | x | x | x | x | x | 50 |
| 21 | ∘ | ∘ | x | x | x | x | x | x | x | Not |
| | | | | | | | | | | measurable |
| 22 | ∘ | ∘ | x | x | x | x | x | x | x | 10 |

In this example 1, the state of strain of the anodized film in working example numbers 1 through 68 was compressive strain, because the anodization treatment was performed under conditions where the solution temperature was less than 50 degree C. In contrast, the state of strain of the anodized film in comparison example numbers 1 through 18 was tensile strain, because the anodization treatment was performed under conditions where the solution temperature was below 50 degree C. Note that there were examples where the Young's modulus could not be measured. Also, comparison example numbers 19 through 22 had a film thickness of 1 micrometer, which is thinner than in working example numbers 1 through 68.

From to the above facts, anodized films in which the porous layer had compressive strain were obtained using an aqueous solution made from an acid having a pKa of 2.5-3.5 at 25 degree C., by performing anodization in that acidic aqueous solution at 50-98 degree C.

The thermal strain resistance and insulation breakdown voltage were each compared for working example numbers 1 through 68 having compressive strain, comparison example numbers 1 through 18 having tensile strain and comparison example numbers 19 through 22 having a thin anodized film.

Compared to comparison example numbers 1 through 22, working example numbers 1 through 68 did not exhibit cracking until a higher temperature, and the thermal strain resistance of working example numbers 1 through 68 was high. In working example numbers 33 through 68, in which the thermal expansion coefficient was controlled by using a composite metal substrate as the base, cracking did not occur until an even higher temperature, and thermal strain resistance was very high.

Compared to comparison example numbers 19 through 22 in which the film thickness was 1 micrometer, working example numbers 1 through 68 had higher insulation breakdown voltage. Further, working example numbers 1 through 68 had an insulation breakdown voltage of 200 V or higher, which is sufficient for a substrate with an insulation layer used in semiconductor devices and the like to which high voltage is applied and in solar cells.

Further, compared to the other working examples, working example numbers 31, 32, 67 and 68, in which the film thickness was 25 micrometers, had somewhat lower thermal strain resistance.

### Example 2

Example 2, anodization treatment was performed on metal substrates under the conditions shown in Tables 7 and 8, forming anodized films to serve as insulation layers. After that, annealing treatment was performed under the annealing conditions shown in Tables 7 and 8. By annealing the anodized films in this way, metal substrates with an insulation layer of working example numbers 70 through 111 and comparison example numbers 30 through 32 shown in Tables 7 and 8 were manufactured. Then, for each of the metal substrates with an insulation layer of working example numbers 70 through 111 and comparison example numbers 30 through 32, the magnitude of strain and Young's modulus of the anodized film which forms the insulation layer were measured, and internal stress was calculated. Further, a thermal strain test and an insulation breakdown test were performed, and thermal strain resistance and insulation breakdown voltage were assessed.

Note that in working example numbers 82 through III, metal substrates with an insulation layer were each produced using a composite substrate of aluminum and another metal, and the anodized film that forms the insulation layer was assessed.

Since the magnitude of strain, Young's modulus and internal strain of the anodized films were measured in the same way as in the example 1 above, their detailed descriptions are omitted.

Further, the thermal strain test and insulation breakdown test were conducted in the same was as in the example 1 above, and thermal strain resistance and insulation breakdown voltage were assessed in the same way as in the example 1 above. The results are shown in Table 9 and Table 10.

TABLE 7

Anodization Conditions

| Working | | | Solution | | Film | Annealing Conditions | |
|---|---|---|---|---|---|---|---|
| Example | Metallic | Electrolytic | Temperature | Voltage | Thickness | | Temperature |
| No. | Substrate | Solution | (degree C.) | (V) | (micrometer) | Atmosphere | (degree C.) |
| 70 | [2] | 0.5M oxalic acid | 16 | 40 | 10 | Vacuum | 120 |
| 71 | [2] | 0.5M oxalic acid | 16 | 40 | 10 | Vacuum | 120 |
| 72 | [2] | 0.5M oxalic acid | 16 | 40 | 3 | Vacuum | 120 |
| 73 | [2] | 0.5M oxalic acid | 16 | 40 | 5 | Vacuum | 120 |
| 74 | [2] | 1M sulfuric acid | 35 | 15 | 10 | Vacuum | 120 |
| 75 | [2] | 1M sulfuric acid | 35 | 15 | 10 | Vacuum | 120 |
| 76 | [2] | 1M sulfuric acid | 35 | 15 | 3 | Vacuum | 120 |
| 77 | [2] | 1M sulfuric acid | 35 | 15 | 5 | Vacuum | 120 |
| 78 | [2] | 1M malonic acid | 80 | 80 | 10 | Vacuum | 120 |
| 79 | [2] | 1M malonic acid | 80 | 80 | 10 | Vacuum | 120 |
| 80 | [2] | 1M malonic acid | 80 | 80 | 3 | Vacuum | 120 |
| 81 | [2] | 1M malonic acid | 80 | 80 | 5 | Vacuum | 120 |
| 82 | [3] | 0.5M oxalic acid | 16 | 40 | 10 | Vacuum | 350 |
| 83 | [3] | 0.5M oxalic acid | 16 | 40 | 10 | Vacuum | 350 |
| 84 | [4] | 0.5M oxalic acid | 16 | 40 | 10 | Vacuum | 150 |
| 85 | [4] | 0.5M oxalic acid | 16 | 40 | 10 | Vacuum | 250 |
| 86 | [4] | 0.5M oxalic acid | 16 | 40 | 10 | Vacuum | 350 |
| 87 | [4] | 0.5M oxalic acid | 16 | 40 | 10 | Vacuum | 450 |
| 88 | [4] | 0.5M oxalic acid | 16 | 40 | 10 | Vacuum | 350 |
| 89 | [4] | 0.5M oxalic acid | 16 | 40 | 10 | Vacuum | 350 |
| 90 | [4] | 0.5M oxalic acid | 16 | 40 | 10 | Vacuum | 350 |
| 91 | [4] | 0.5M oxalic acid | 16 | 40 | 10 | Vacuum | 350 |
| 92 | [4] | 0.5M oxalic acid | 16 | 40 | 10 | Vacuum | 350 |
| 93 | [4] | 1M sulfuric acid | 35 | 15 | 10 | Vacuum | 250 |
| 94 | [4] | 1M sulfuric acid | 35 | 15 | 10 | Vacuum | 350 |

| | Annealing | | | | | |
|---|---|---|---|---|---|---|
| Working | Conditions | | | Young's | | |
| Example | Time | Strain at Room | | Modulus | Internal Stress | |
| No. | (minutes) | Temperature | | (GPa) | (MPa) | |
| 70 | 20 | 0.120% | Compressive | 115 | 138 | Compressive |
| 71 | 60 | 0.101% | Compressive | 105 | 106 | Compressive |
| 72 | 20 | 0.114% | Compressive | 108 | 123 | Compressive |
| 73 | 20 | 0.119% | Compressive | 110 | 131 | Compressive |
| 74 | 20 | 0.106% | Compressive | 82 | 87 | Compressive |
| 75 | 60 | 0.110% | Compressive | 75 | 83 | Compressive |
| 76 | 20 | 0.109% | Compressive | 86 | 94 | Compressive |
| 77 | 20 | 0.102% | Compressive | 77 | 79 | Compressive |
| 78 | 20 | 0.152% | Compressive | 81 | 123 | Compressive |
| 79 | 60 | 0.162% | Compressive | 93 | 151 | Compressive |
| 80 | 20 | 0.134% | Compressive | 82 | 110 | Compressive |
| 81 | 20 | 0.142% | Compressive | 86 | 122 | Compressive |
| 82 | 1 | 0.064% | Compressive | 118 | 76 | Compressive |
| 83 | 15 | 0.104% | Compressive | 105 | 109 | Compressive |
| 84 | 15 | 0.015% | Compressive | 121 | 18 | Compressive |
| 85 | 15 | 0.052% | Compressive | 108 | 56 | Compressive |
| 86 | 15 | 0.118% | Compressive | 129 | 152 | Compressive |
| 87 | 15 | 0.133% | Compressive | Not | — | Compressive |
| | | | | measurable | | |
| 88 | 15 | 0.095% | Compressive | 112 | 106 | Compressive |
| 89 | 1 | 0.059% | Compressive | 129 | 76 | Compressive |
| 90 | 100 | 0.123% | Compressive | Not | — | Compressive |
| | | | | measurable | | |
| 91 | 200 | 0.127% | Compressive | 112 | 142 | Compressive |
| 92 | 1000 | 0.131% | Compressive | 121 | 159 | Compressive |
| 93 | 15 | 0.042% | Compressive | 72 | 30 | Compressive |
| 94 | 15 | 0.110% | Compressive | 67 | 74 | Compressive |

TABLE 8

| | | Anodization Conditions | | | | | |
|---|---|---|---|---|---|---|---|
| Working | | | Solution | | Film | Annealing Conditions | |
| Example | Metallic | Electrolytic | Temperature | Voltage | Thickness | | Temperature |
| No. | Substrate | Solution | (degree C.) | (V) | (micrometer) | Atmosphere | (degree C.) |
| 95 | [4] | 1M sulfuric acid | 35 | 15 | 10 | Vacuum | 450 |
| 96 | [4] | 1M sulfuric acid | 35 | 15 | 10 | Vacuum | 350 |
| 97 | [4] | 1M sulfuric acid | 35 | 15 | 10 | Vacuum | 350 |
| 98 | [4] | 0.5M oxalic acid | 35 | 15 | 10 | Vacuum | 350 |
| 99 | [4] | 1M sulfuric acid | 35 | 15 | 10 | Vacuum | 350 |
| 100 | [4] | 1M malonic acid | 80 | 80 | 10 | Vacuum | 250 |
| 101 | [4] | 1M malonic acid | 80 | 80 | 10 | Vacuum | 350 |
| 102 | [4] | 1M malonic acid | 80 | 80 | 10 | Vacuum | 450 |
| 103 | [4] | 1M malonic acid | 80 | 80 | 10 | Vacuum | 350 |
| 104 | [4] | 1M malonic acid | 80 | 80 | 10 | Vacuum | 350 |
| 105 | [4] | 1M malonic acid | 80 | 80 | 10 | Vacuum | 350 |
| 106 | [4] | 0.5M oxalic acid | 16 | 40 | 3 | Vacuum | 350 |
| 107 | [4] | 0.5M oxalic acid | 16 | 40 | 5 | Vacuum | 350 |
| 108 | [4] | 1M sulfuric acid | 35 | 15 | 3 | Vacuum | 350 |
| 109 | [4] | 1M sulfuric acid | 35 | 15 | 5 | Vacuum | 350 |
| 110 | [4] | 1M malonic acid | 80 | 80 | 3 | Vacuum | 350 |
| 111 | [4] | 1M malonic acid | 80 | 80 | 5 | Vacuum | 350 |
| Comparison | [4] | 0.5M oxalic acid | 16 | 40 | 1 | Vacuum | 350 |
| example | | | | | | | |
| No. 30 | | | | | | | |
| Comparison | [4] | 1M sulfuric acid | 35 | 15 | 1 | Vacuum | 350 |
| example | | | | | | | |
| No. 31 | | | | | | | |
| Comparison | [4] | 1M malonic acid | 80 | 80 | 1 | Vacuum | 350 |
| example | | | | | | | |
| No. 32 | | | | | | | |

| | Annealing | | | | | |
|---|---|---|---|---|---|---|
| Working | Conditions | | | Young's | | |
| Example | Time | Strain at Room | | Modulus | Internal Stress | |
| No. | (minutes) | Temperature | | (GPa) | (MPa) | |
| 95 | 15 | 0.088% | Compressive | 65 | 57 | Compressive |
| 96 | 5 | 0.097% | Compressive | 71 | 69 | Compressive |
| 97 | 100 | 0.102% | Compressive | 79 | 81 | Compressive |
| 98 | 200 | 0.119% | Compressive | 68 | 81 | Compressive |
| 99 | 1000 | 0.124% | Compressive | 71 | 88 | Compressive |
| 100 | 15 | 0.054% | Compressive | 79 | 43 | Compressive |
| 101 | 15 | 0.102% | Compressive | 72 | 73 | Compressive |
| 102 | 15 | 0.172% | Compressive | 69 | 119 | Compressive |
| 103 | 5 | 0.047% | Compressive | 78 | 37 | Compressive |
| 104 | 100 | 0.120% | Compressive | 75 | 90 | Compressive |
| 105 | 1000 | 0.123% | Compressive | 76 | 93 | Compressive |
| 106 | 15 | 0.131% | Compressive | 119 | 156 | Compressive |
| 107 | 15 | 0.119% | Compressive | 116 | 138 | Compressive |
| 108 | 15 | 0.119% | Compressive | 74 | 88 | Compressive |
| 109 | 15 | 0.096% | Compressive | 62 | 60 | Compressive |
| 110 | 15 | 0.126% | Compressive | 76 | 96 | Compressive |
| 111 | 15 | 0.093% | Compressive | 69 | 64 | Compressive |
| Comparison | 15 | Not | — | Not | — | — |
| example | | measurable | | measured | | |
| No. 30 | | | | | | |
| Comparison | 15 | Not | — | Not | — | — |
| example | | measurable | | measured | | |
| No. 31 | | | | | | |
| Comparison | 15 | Not | — | Not | — | — |
| example | | measurable | | measured | | |
| No. 32 | | | | | | |

TABLE 9

| Working | Thermal Strain Test | | | | | | | | | | Insulation |
|---|---|---|---|---|---|---|---|---|---|---|---|
| Example | Heating Temperature (degree C.) | | | | | | | | | | Breakdown |
| No. | 120 | 150 | 180 | 210 | 230 | 450 | 500 | 550 | 575 | 590 | Voltage (V) |
| 70 | ∘ | ∘ | ∘ | ∘ | x | x | x | x | x | x | 910 |
| 71 | ∘ | ∘ | ∘ | ∘ | x | x | x | x | x | x | 890 |
| 72 | ∘ | ∘ | Δ | x | x | x | x | x | x | x | 260 |
| 73 | ∘ | ∘ | ∘ | Δ | x | x | x | x | x | x | 570 |
| 74 | ∘ | ∘ | ∘ | Δ | x | x | x | x | x | x | 840 |
| 75 | ∘ | ∘ | ∘ | ∘ | x | x | x | x | x | x | 890 |
| 76 | ∘ | ∘ | ∘ | ∘ | x | x | x | x | x | x | 290 |
| 77 | ∘ | ∘ | ∘ | ∘ | Δ | x | x | x | x | x | 490 |
| 78 | ∘ | ∘ | ∘ | ∘ | Δ | x | x | x | x | x | 910 |
| 79 | ∘ | ∘ | ∘ | ∘ | Δ | x | x | x | x | x | 1000 V |
| | | | | | | | | | | | or more |
| 80 | ∘ | ∘ | ∘ | ∘ | x | x | x | x | x | x | 310 |
| 81 | ∘ | ∘ | ∘ | ∘ | Δ | x | x | x | x | x | 470 |
| 82 | ∘ | ∘ | ∘ | ∘ | ∘ | Δ | Δ | x | x | x | 960 |
| 83 | ∘ | ∘ | ∘ | ∘ | ∘ | ∘ | ∘ | Δ | x | x | 890 |
| 84 | ∘ | ∘ | ∘ | ∘ | ∘ | ∘ | Δ | x | x | x | 910 |
| 85 | ∘ | ∘ | ∘ | ∘ | ∘ | ∘ | Δ | x | x | x | 830 |
| 86 | ∘ | ∘ | ∘ | ∘ | ∘ | ∘ | ∘ | Δ | Δ | x | 790 |
| 87 | ∘ | ∘ | ∘ | ∘ | ∘ | ∘ | ∘ | ∘ | Δ | x | 870 |
| 88 | ∘ | ∘ | ∘ | ∘ | ∘ | ∘ | ∘ | Δ | Δ | x | 930 |
| 89 | ∘ | ∘ | ∘ | ∘ | ∘ | ∘ | Δ | Δ | x | x | 980 |
| 90 | ∘ | ∘ | ∘ | ∘ | ∘ | ∘ | ∘ | Δ | x | x | 770 |
| 91 | ∘ | ∘ | ∘ | ∘ | ∘ | ∘ | ∘ | ∘ | x | x | 910 |
| 92 | ∘ | ∘ | ∘ | ∘ | ∘ | ∘ | ∘ | Δ | x | x | 890 |
| 93 | ∘ | ∘ | ∘ | ∘ | ∘ | ∘ | ∘ | x | x | x | 850 |
| 94 | ∘ | ∘ | ∘ | ∘ | ∘ | ∘ | ∘ | Δ | Δ | x | 860 |

TABLE 10

| Working | Thermal Strain Test | | | | | | | | | | Insulation |
|---|---|---|---|---|---|---|---|---|---|---|---|
| Example | Heating Temperature (degree C.) | | | | | | | | | | Breakdown |
| No. | 120 | 150 | 180 | 210 | 230 | 450 | 500 | 550 | 575 | 590 | Voltage (V) |
| 95 | ∘ | ∘ | ∘ | ∘ | ∘ | ∘ | ∘ | ∘ | Δ | x | 980 |
| 96 | ∘ | ∘ | ∘ | ∘ | ∘ | ∘ | ∘ | ∘ | x | x | 890 |
| 97 | ∘ | ∘ | ∘ | ∘ | ∘ | ∘ | ∘ | Δ | Δ | x | 910 |
| 98 | ∘ | ∘ | ∘ | ∘ | ∘ | ∘ | ∘ | ∘ | Δ | x | 980 |
| 99 | ∘ | ∘ | ∘ | ∘ | ∘ | ∘ | ∘ | ∘ | Δ | x | 790 |
| 100 | ∘ | ∘ | ∘ | ∘ | ∘ | ∘ | ∘ | ∘ | x | x | 1000 V |
| | | | | | | | | | | | or more |
| 101 | ∘ | ∘ | ∘ | ∘ | ∘ | ∘ | ∘ | ∘ | ∘ | x | 890 |
| 102 | ∘ | ∘ | ∘ | ∘ | ∘ | ∘ | ∘ | ∘ | ∘ | x | 930 |
| 103 | ∘ | ∘ | ∘ | ∘ | ∘ | ∘ | ∘ | ∘ | ∘ | x | 870 |
| 104 | ∘ | ∘ | ∘ | ∘ | ∘ | ∘ | ∘ | ∘ | ∘ | x | 1000 V |
| | | | | | | | | | | | or more |
| 105 | ∘ | ∘ | ∘ | ∘ | ∘ | ∘ | ∘ | ∘ | ∘ | x | 880 |
| 106 | ∘ | ∘ | ∘ | ∘ | ∘ | ∘ | Δ | x | x | x | 250 |
| 107 | ∘ | ∘ | ∘ | ∘ | ∘ | ∘ | ∘ | Δ | x | x | 490 |
| 108 | ∘ | ∘ | ∘ | ∘ | ∘ | ∘ | ∘ | ∘ | x | x | 290 |
| 109 | ∘ | ∘ | ∘ | ∘ | ∘ | ∘ | ∘ | ∘ | Δ | x | 530 |
| 110 | ∘ | ∘ | ∘ | ∘ | ∘ | ∘ | ∘ | ∘ | x | x | 310 |
| 111 | ∘ | ∘ | ∘ | ∘ | ∘ | ∘ | ∘ | ∘ | Δ | x | 520 |
| Comparison | ∘ | ∘ | ∘ | ∘ | ∘ | ∘ | ∘ | Δ | x | x | 20 |
| example | | | | | | | | | | | |
| No. 30 | | | | | | | | | | | |
| Comparison | ∘ | ∘ | ∘ | ∘ | ∘ | ∘ | ∘ | ∘ | x | x | 10 |
| example | | | | | | | | | | | |
| No. 31 | | | | | | | | | | | |
| Comparison | ∘ | ∘ | ∘ | ∘ | ∘ | ∘ | ∘ | ∘ | x | x | 40 |
| example | | | | | | | | | | | |
| No. 32 | | | | | | | | | | | |

In this example 2, annealing treatment was performed. Working example numbers 70 and 71 and comparison example number 17 of the above example 1 underwent annealing treatment. Working example numbers 74 and 75 and comparison examples number 18 of the above example 1 underwent annealing treatment. By annealing treatment, the anodized film changed from tensile strain to compressive strain.

Further, working example numbers 78 and 79 and comparison example number 17 of the above example 1 underwent annealing treatment. By annealing, compressive strain in working example number 17 of the above example 1 was 0.086%, but it was 0.152% in working example number 78 and 0.162% in working example number 79, meaning that the compressive strain of the anodized films became larger.

Therefore, the strain of the porous layer of the anodized films could be considered to be the compressive strain at room temperature. Further, the higher the annealing heating temperature, the higher the magnitude of strain. Even when the annealing environment differed (in vacuum, in air at atmospheric pressure), it could be considered to be the compressive strain at room temperature.

Compared to comparison example numbers 30 through 32, working example numbers 70 through 81 did not exhibit cracking until a higher temperature, and the thermal strain resistance of the working examples was high. In working example numbers 82 through III, in which the thermal expansion coefficient was controlled by using a composite metal substrate as the base, cracking did not occur until an even higher temperature, and thermal strain resistance was very high.

Further, the longer the annealing time and the higher the annealing temperature, the higher the temperature at which cracking was inhibited.

Compared to comparison example numbers 30 through 32 in which the coating thickness was 1 micrometer, working example numbers 70 through 111 had higher insulation breakdown voltage. Further, working example numbers 70 through 111 had an insulation breakdown voltage of 200 V or higher, which is sufficient for a substrate with an insulation layer used in semiconductor devices and the like to which high voltage is applied and in solar cells.

Therefore, it can be said that when compressive strain acts on the anodized film, a metal substrate with an insulation layer having high cracking resistance and high insulation reliability is obtained. On the other hand, when compressive strain is small or tensile strain acts on the anodized film, a metal substrate with an insulation layer having low cracking resistance and lacking sufficient insulation reliability is obtained. Further, when the anodized film is thin, a metal substrate having sufficient insulation properties cannot be obtained. Additionally, when the anodized film is thin, a metal substrate having high cracking resistance cannot be obtained.

### Example 3

Example 3, the metal substrates with an insulation layer of working example numbers 120 through 125 and comparison example numbers 40 through 43 shown below were manufactured, and the magnitude of strain and Young's modulus of the anodized film were measured for each, and internal stress was calculated. The results are shown in Table 11.

Further, a bending strain test was performed for the substrates with an insulation layer of working example numbers 120 through 125 and comparison example numbers 40 through 43, and the reduction in bending strain resistance was assessed. The results are shown in Table 12.

In this example 3, anodization treatment was performed under the conditions shown in Table 11 on the metal substrates shown in Table 11, thereby forming an anodized film serving as an insulation layer, and the substrates with an insulation layer of working example numbers 120 through 125 and comparison example numbers 40 through 43 were thus obtained. In this example 3, in working example numbers 120 through 125, the metal substrate was bent to the curvature shown in Table 11 using a jig when the metal substrate was set in the anodization tank, and then anodization was performed. On the other hand, comparison example numbers 40 through 43 were anodized without curvature, as shown in Table 11.

In this example 3, since the magnitude of strain, Young's modulus and internal strain of the anodized films were measured in the same way as in the example 1 above, their detailed descriptions are omitted.

Further, in the bending strain test, the metal substrates with an insulation layer were cut into test specimens measuring 3 cm wide by 10 cm long. Each test specimen was bent along a jig having the radius of curvature shown in Table 11, and the surface of the specimen was observed by optical microscope.

In the bending strain test, bending strain resistance was assessed by the degree of cracking. If no cracking was seen in the test specimen, the example was marked with an O. If cracking occurred but stopped part way through the 3 cm width, it was marked with a triangle. If cracking occurred along the entire surface of the test specimen, it was marked with an X.

In Table 11 below, [1] shown in the Metallic Substrate column indicates the structure of the substrate. As this was described in detail in the example 1, its detailed description will be omitted.

TABLE 11

| | | Anodization Conditions | | | | Metallic | | |
|---|---|---|---|---|---|---|---|---|
| | | | Solution | | Film | Substrate | Radius of | |
| | Metallic | Electrolytic | Temperature | Voltage | Thickness | Thickness | Curvature | |
| | Substrate | Solution | (degree C.) | (V) | (micrometer) | (micrometer) | (mm) | Elongation |
| Working | [1] | 0.5M oxalic acid | 16 | 40 | 10 | 300 | 600 | 0.03% |
| Example | | | | | | | | |
| No. 120 | | | | | | | | |
| Working | [1] | 0.5M oxalic acid | 16 | 40 | 10 | 300 | 300 | 0.05% |
| Example | | | | | | | | |
| No. 121 | | | | | | | | |
| Working | [1] | 1M sulfuric acid | 16 | 15 | 10 | 300 | 300 | 0.05% |
| Example | | | | | | | | |
| No. 122 | | | | | | | | |
| Working | [1] | 1M sulfuric acid | 35 | 15 | 10 | 300 | 300 | 0.05% |
| Example | | | | | | | | |
| No. 123 | | | | | | | | |
| Working | [1] | 1M phosphoric acid | 5 | 100 | 10 | 300 | 300 | 0.05% |
| Example | | | | | | | | |
| No. 124 | | | | | | | | |
| Working | [1] | 1M malonic acid | 80 | 80 | 10 | 100 | 300 | 0.05% |
| Example | | | | | | | | |
| No. 125 | | | | | | | | |
| Comparison | [1] | 0.5M oxalic acid | 16 | 40 | 10 | 300 | — | — |
| example | | | | | | | | |
| No. 40 | | | | | | | | |
| Comparison | [1] | 1M sulfuric acid | 16 | 15 | 10 | 300 | — | — |
| example | | | | | | | | |
| No. 41 | | | | | | | | |
| Comparison | [1] | 1M sulfuric acid | 35 | 15 | 10 | 300 | — | — |
| example | | | | | | | | |
| No. 42 | | | | | | | | |
| Comparison | [1] | 1M phosphoric acid | 5 | 100 | 10 | 300 | — | — |
| example | | | | | | | | |
| No. 43 | | | | | | | | |

| | Strain at Room | | Elongation | | Young's | | |
|---|---|---|---|---|---|---|---|
| | Temperature (direction | | Direction | | Modulus | Internal Stress | |
| | of elongation) | | and strain | | (GPa) | (MPa) | |
| Working | 0.015% | Compressive | 0.003% | Tensile | 114 | 14 | Compressive |
| Example | | | | | | | |
| No. 120 | | | | | | | |
| Working | 0.035% | Compressive | 0.002% | Tensile | 120 | 40 | Compressive |
| Example | | | | | | | |
| No. 121 | | | | | | | |
| Working | 0.042% | Compressive | 0.013% | Tensile | 71 | 21 | Compressive |
| Example | | | | | | | |
| No. 122 | | | | | | | |
| Working | 0.040% | Compressive | 0.005% | Tensile | 67 | 23 | Compressive |
| Example | | | | | | | |
| No. 123 | | | | | | | |
| Working | 0.0.65% | Compressive | 0.031% | Tensile | 132 | 45 | Compressive |
| Example | | | | | | | |
| No. 124 | | | | | | | |
| Working | 0.095% | Compressive | 0.074% | Compressive | 73 | 123 | Compressive |
| Example | | | | | | | |
| No. 125 | | | | | | | |
| Comparison | 0.008% | Tensile | — | — | 112 | 9 | Tensile |
| example | | | | | | | |
| No. 40 | | | | | | | |
| Comparison | 0.002% | Tensile | — | — | 76 | 2 | Tensile |
| example | | | | | | | |
| No. 41 | | | | | | | |
| Comparison | 0.010% | Tensile | — | — | 60 | 6 | Tensile |
| example | | | | | | | |
| No. 42 | | | | | | | |
| Comparison | 0.034% | Tensile | — | — | 125 | 43 | Tensile |
| example | | | | | | | |
| No. 43 | | | | | | | |

TABLE 12

| | Bending Strain Test | | | | |
|---|---|---|---|---|---|
| | Radius of Curvature (mm) | | | | |
| | 20 | 30 | 50 | 80 | 100 |
| Working example No. 120 | X | X | Δ | ◯ | ◯ |
| Working example No. 121 | X | X | Δ | ◯ | ◯ |
| Working example No. 122 | X | X | X | X | ◯ |
| Working example No. 123 | X | X | X | X | ◯ |
| Working example No. 124 | X | X | X | ◯ | ◯ |
| Working example No. 125 | X | Δ | ◯ | ◯ | ◯ |
| Comparison example No. 40 | X | X | X | ◯ | ◯ |
| Comparison example No. 41 | X | X | X | X | Δ |
| Comparison example No. 42 | X | X | X | X | ◯ |
| Comparison example No. 43 | X | X | X | X | ◯ |

In working example numbers 120 through 125, the state of strain of the anodized film was compressive strain, because the anodization treatment was performed under conditions where the metal substrate was elongated. In contrast, the state of strain of the anodized film in comparison example numbers 40 through 43 was tensile strain, because the anodization treatment was performed without elongating the metallic substrate.

In this example 3 as well, bending strain resistance was compared for working example numbers 120 through 125 having compressive strain and comparison example numbers 40 through 43 having tensile strain.

As shown in Table 12, compared to comparison example numbers 40 through 43, working example numbers 120 through 125 had high bending strain resistance.

Therefore, by anodizing the metal substrate in the state where it is elongated more than in the state of use at room temperature, an anodized film in which the porous layer has compressive strain is obtained.

Further, it can be said that when compressive strain acts on the anodized film, a metal substrate with an insulation layer having high cracking resistance is obtained. On the other hand, when compressive strain is small or tensile strain acts on the anodized film, a metal substrate with an insulation layer having high cracking resistance cannot be obtained.

### LEGEND

10 substrate
12 metal base
14 aluminum base (Al base)
16 insulation layer
30 thin-film solar cell
32 back electrodes
34 photoelectric conversion layers
36 buffer layer
38 transparent electrodes
40 photoelectric conversion elements
42 first conductive member
44 second conductive member
50 alkali supply layer

1-68. (canceled)

69. A metal substrate with an insulation layer, comprising:
a metal substrate having at least an aluminum base; and a porous type anodized film of aluminum formed on said aluminum base of said metal substrate, wherein said anodized film comprises a barrier layer portion and a porous layer portion, and at least said porous layer portion has compressive strain at room temperature.

70. The metal substrate with an insulation layer according to claim 69, wherein said metal substrate is composed of said aluminum base, and said anodized film is formed on at least one surface of said aluminum base.

71. The substrate with an insulation layer according to claim 69, wherein said metallic substrate further includes a metal base, and said aluminum base is formed on at least one surface of said metal base.

72. The substrate with an insulation layer according to claim 69, wherein said metallic substrate further includes a metal base made of metal having a larger Young's modulus than aluminum, said aluminum base is formed on at least one surface of said metal base, and said anodized film is formed on a surface of said aluminum base.

73. A method for manufacturing a metal substrate with an insulation layer, comprising: preparing a metallic substrate having at least an aluminum base; and forming a porous type anodized film of aluminum as an insulation layer on said aluminum base of said metallic substrate, wherein said anodized film comprises a barrier layer portion and a porous layer portion, and at least said porous layer portion has compressive strain at a room temperature.

74. The manufacturing method according to claim 73, wherein the step of forming said porous type anodized film of aluminum having said compressive strain comprises a step of forming said porous type anodized film of aluminum in a state where said metal substrate is elongated more than in a state of use at a room temperature.

75. The manufacturing method according to claim 74, wherein the step of forming said anodized film comprises a step of anodizing said aluminum base of said metal substrate in an acidic aqueous solution at a temperature of 50 degree C. to 98 degree C., said acidic aqueous solution having an acid dissociation constant (pKa) of 2.5 to 3.5 at a temperature of 25 degree C.

76. The manufacturing method according to claim 73, wherein the step of forming said porous type anodized film of aluminum having said compressive strain comprises:
a step of subjecting said aluminum base of said metal substrate to an anodization treatment to form a first anodized film of aluminum on said aluminum base; and
a step of subjecting the thus formed first anodized film to a heat treatment at a heating temperature of 100 degree C. to 600 degree C.

77. The manufacturing method according to claim 76, wherein said first anodized film subjected to the heat treatment in said step of said heat treatment has tensile strain.

78. The manufacturing method according to claim 76, wherein a heat treatment condition in said step of said heat treatment comprises a heating time of 1 second to 100 hours.

79. The manufacturing method according to claim 73, wherein said metallic substrate further includes a metal base, and said aluminum base is formed on at least one surface of said metal base.

80. The manufacturing method according to claim 73, wherein said metallic substrate further includes a metal base made of metal having a larger Young's modulus than aluminum, said aluminum base is formed on at least one surface of said metal base, and said anodized film is formed on a surface of said aluminum base.

81. A semiconductor device, comprising:
the metal substrate with an insulation layer according to claim 69 employed as a substrate;
a semiconductor element formed on said metal substrate with the insulation layer.

82. A method for manufacturing a semiconductor device, comprising:
manufacturing the metal substrate with an insulation layer by using the method for manufacturing a metal substrate with an insulation layer according to claim 73; and forming semiconductor elements on said metal substrate with the insulation layer, wherein the step of manufacturing said metal substrate with the insulation layer and the step of forming said semiconductor elements are performed in an integrated manner by a roll-to-roll process.

83. A solar cell, comprising:
a photoelectric conversion layer;
the metal substrate with an insulation layer according to claim 69 employed as a substrate, wherein at least said photoelectric conversion layer is formed on said metal substrate with the insulation layer.

84. A method for manufacturing a solar cell, comprising:
a step of manufacturing the metal substrate with an insulation layer by using the method for manufacturing a metal substrate with an insulation layer according to claim 73; and a film deposition step of forming at least a compound-based photoelectric conversion layer on said metal substrate with the insulation layer, wherein the step of manufacturing said metal substrate with the insulation layer and the film deposition step are performed in an integrated manner by a roll-to-roll process.

85. An electronic circuit, comprising:
the metal substrate with an insulation layer according to claim 69 employed as a substrate;
electronic elements formed on said metal substrate with the insulation layer.

86. A method for manufacturing an electronic circuit, comprising:
manufacturing the metal substrate with an insulation layer by using the method for manufacturing a metal substrate with an insulation layer according to claim 73; and forming electronic elements on said metal substrate with the insulation layer, wherein the step of manufacturing said metal substrate with the insulation layer and the step of forming said electronic elements are performed in an integrated manner by a roll-to-roll process.

87. A light-emitting device, comprising:
the metal substrate with an insulation layer according to claim 69 employed as a substrate;
light-emitting elements formed on said metal substrate with the insulation layer.

88. A method for manufacturing a light-emitting device, comprising:
manufacturing the metal substrate with an insulation layer by using the method for manufacturing a metal substrate with an insulation layer according to claim 73; and forming light-emitting elements on said metal substrate with the insulation layer, wherein the step of manufacturing said metal substrate with the insulation layer and the step of forming said light-emitting elements are performed in an integrated manner by a roll-to-roll process.
